(19) United States
(12) Patent Application Publication
(10) Pub. No.: US 2015/0289384 A1
(43) Pub. Date: Oct. 8, 2015

(54) CONDUCTIVE FILM AND METHOD FOR MANUFACTURING SAME, AND RESIN ARTICLE WITH PLATING LAYER AND METHOD FOR MANUFACTURING SAME

(71) Applicant: CANON COMPONENTS, INC., Saitama-ken (JP)

(72) Inventor: Taisuke IWASHITA, Saitama-ken (JP)

(21) Appl. No.: 14/677,487

(22) Filed: Apr. 2, 2015

(30) Foreign Application Priority Data
Apr. 4, 2014 (JP) 2014-078220
Aug. 6, 2014 (JP) 2014-160782
Dec. 26, 2014 (JP) 2014-265249

(51) Int. Cl. H05K 3/18; H05K 1/02; H05K 3/24; H05K 1/03; H05K 1/09

(52) U.S. Cl. CPC H05K 3/185; H05K 3/188; H05K 1/032; H05K 1/09; H05K 3/244; H05K 1/0296

(57) ABSTRACT

There is provided with a conductive film. The conductive film has a resin article having a modified portion on a surface thereof, the modified portion being formed by irradiation with an ultraviolet laser and an oxidation process after the irradiation with the ultraviolet laser. The conductive film also has a conductor provided by plating on the modified portion irradiated with the ultraviolet laser.

### BACKGROUND OF THE INVENTION

1. Field of the Invention

The present invention relates to conductive films and methods for manufacturing the conductive films, and resin articles with plating layer and methods for manufacturing the resin articles.

2. Description of the Related Art

A conductive film which includes a resin film as a base is expected to have applications in the fields of the electromagnetic wave shield, touch panel sensor, organic EL device, solar cell, and the like. In particular, a transparent conductive film in which conductive lines are formed on a resin film, for example, in a mesh pattern, is expected to be advantageous over a transparent conductive film in which an indium tin oxide (ITO) layer is formed on an entire resin film, in terms of cost, because the former does not require a rare metal, such as indium or the like.

Japanese Patent Laid-Open No. 10-41682 describes a technique of forming a metal layer having a predetermined pattern, such as mesh or the like, by performing printing on a transparent substrate using a catalyst paste according to a predetermined pattern, and then performing electroless plating. Japanese Patent Laid-Open No. 11-170420 describes a technique of manufacturing an electromagnetic wave shield film by attaching a metal foil to a transparent plastic base, and then performing chemical etching to form a geometric pattern of the metal foil.

### SUMMARY OF THE INVENTION

According to an embodiment of the present invention, a conductive film comprises: a resin article having a modified portion on a surface thereof, the modified portion being formed by irradiation with an ultraviolet laser and an oxidation process after the irradiation with the ultraviolet laser; and a conductor provided by plating on the modified portion irradiated with the ultraviolet laser.

According to another embodiment of the present invention, a method for manufacturing a conductive film comprises steps of: irradiating a portion on which a conductor is to be formed on a resin article with an ultraviolet laser; after the irradiating step, oxidizing the resin article; after the oxidizing step, forming the conductor on the ultraviolet laser irradiated portion of the resin article, including performing electroless plating on the resin article.

According to still another embodiment of the present invention, a resin article with plating layer comprises: a resin article; and a plating layer provided on a surface of the resin article, Wherein the plating layer exhibits a black color.

According to yet another embodiment of the present invention, a method for manufacturing a resin article with plating layer comprises steps of: modifying a portion of a surface of the resin article by irradiation with an ultraviolet light; and forming the plating layer by plating on the portion of the surface of the resin article, the plating layer exhibiting a black color.

Further features of the present invention will become apparent from the following description of exemplary embodiments (with reference to the attached drawings).

### BRIEF DESCRIPTION OF THE DRAWINGS

FIG. 1 is a diagram for describing a method for manufacturing a conductive film according to a first embodiment.

FIG. 2 is a diagram for describing a case where a thickness of an interconnection layer is increased by performing electroless plating or electroplating on a seed layer on a flat and even surface.

FIGS. 3A-3B are diagrams showing a pattern of a conductor formed in the first embodiment.

FIG. 4 is a flowchart of a method for manufacturing the conductive film of the first embodiment.

FIG. 5 is a schematic diagram of the conductive film of the first embodiment.

FIGS. 6A-6B are schematic diagrams of a resin article with plating layer according to a second embodiment.

FIG. 7 is a flowchart of a method for manufacturing the resin article with plating layer of the second embodiment.

FIGS. 8A-8C are diagrams for describing the method for manufacturing the resin article with plating layer of the second embodiment.

FIG. 9 is a graph showing reflectances of plating layers (copper-nickel plating layers) of Examples 1-3 and Comparative Example 1.

FIG. 10 is a diagram for describing a method for forming a plating layer according to the second embodiment.

FIG. 11 is a diagram for describing the method for forming the plating layer of the second embodiment.

### DESCRIPTION OF THE EMBODIMENTS

The technique of Japanese Patent Laid-Open No. 10-41682 above has a problem that it is difficult to reduce the width of the conductive line. The technique of Japanese Patent Laid-Open No. 11-170420 above has a problem that a large amount of liquid waste is produced in the chemical etching process, resulting in environmental unfriendliness and high cost of liquid waste treatment.

According to an embodiment of the present invention, a method for manufacturing a conductive film having a precise conductor pattern at low cost is provided.

Embodiments to which the present invention is available will now be described with reference to the accompanying drawings. Note that the scope of the present invention is not limited by the embodiments below.

### First Embodiment

As shown in FIG. 5, a conductive film 100 according to an embodiment of the present invention includes a resin article 110 having a recessed portion 140 in a surface thereof, and a conductor 520 provided in the recessed portion 140. While, in FIG. 5, the conductor 520 includes an electroless plating layer 130 and an electroplating layer 120, the conductor 520 does not need to include a plurality of layers, as described below. These will now be described in detail with reference to the drawings. As shown in FIG. 5, all or a portion of the conductor 520 is buried in the recessed portion 140 previously formed in the resin article 110.

In the description that follows, the term “conductive film” refers to a resin article on which a conductor is formed, more specifically, for example, a film on which a conductor is formed. A conductive film may, for example, be used as an electrode or the like. However, a conductive film does not need to be used to supply or extract electric power. For example, a conductive film may be used as an electromagnetic wave shield or the like. In particular, a transparent conductive film may be used as an electrode for a display, an electrode for a solar cell, or the like by utilizing the properties that the transparent conductive film is transparent and highly conductive. A conductive film may include other components, such as an external connection terminal and the like, depending on the application. Note that a transparent conductive film does not need to have complete optical transparency. As used herein, a conductive film which can pass at least a portion of incident light is referred to as a “transparent conductive film.”

(Resin Article)

The resin article 110 is not particularly limited. For example, the resin article 110 may be a film of a resin material, and may be suitably selected, depending on the application of the conductive film 100. When a transparent conductive film is produced, a resin material having transparency is selected as the above resin material. In one embodiment, the resin material having transparency has a total luminous transmittance (JIS K7361-1: 1997) of 80% or more. Examples of the resin material having transparency include polyolefin resins such as cycloolefin polymers and polystyrene, polyester resins such as polyethylene terephthalate, vinyl resins such as polyvinyl chloride, and the like. Other examples of the resin material having transparency include polycarbonate and polyimide. As described below, a recessed portion can be formed in a film of these resin materials by irradiating the film with an ultraviolet laser. Also, by irradiating a film of these resin materials with ultraviolet light, the film can be modified so that plating is selectively deposited on the irradiated portion. Therefore, by using a film of these resin materials, a conductive film according to this embodiment can be easily produced. The form of the resin article 110 is not limited to film. The resin article 110 may have any three-dimensional shape. For example, the resin article 110 may be in the shape of a substrate, and the conductive film 100 may also be in the shape of a substrate.

Not all the resin article 110 is essentially formed from a transparent resin material. For example, the resin article 110 may include a portion which is formed from a transparent resin material and a portion which is formed from non-transparent resin material. The resin article 110 may have a multilayer structure including two or more layers. Alternatively, the resin article 110 may be formed from a composite material having a coated structure in which a resin material covers a surface of another material. Still alternatively, an inorganic layer may be provided on top of the resin article 110. In this case, if a surface of the resin article 110 on which the conductor 520 is to be formed is formed from a material which allows for formation and modification of a recessed portion using ultraviolet light, a conductive film according to this embodiment can be easily produced.

In one embodiment, the resin material is a carbon polymer including carbon atoms and hydrogen atoms. The carbon polymer includes cycloolefin polymers. For example, the cycloolefin polymer may include repeating units represented by:

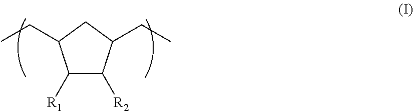

where R₁ and R₂ each independently represent a hydrogen atom or a hydrocarbon group having 1-12 carbon atoms. The hydrocarbon group includes an alkyl group having 1-12 carbon atoms, and the like. Examples of the alkyl group include methyl, ethyl, cyclohexyl, and the like. In one embodiment, R₁ and R₂ are a divalent hydrocarbon group having 1-12 carbon atoms. Examples of the divalent hydrocarbon group include a divalent alkyl group having 1-12 carbon atoms, and the like. Examples of the divalent alkyl group include 1,3-propanediyl, 1,3-cyclopentanediyl, 5-methylcyclopentane-1,3-diyl, and the like. The cycloolefin polymer may, for example, be one which has any of the following repeating units A-E.

| | 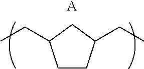 | 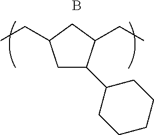 | 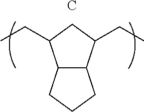 | 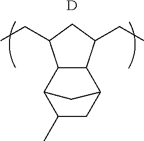 | 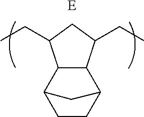 |
|---|---|---|---|---|---|
| Properties | C | A | A | A | A |
| Trans- | N | T | T | T | T |
| parency | | | | | |
| Tg/° C. | 134 (Tm) | 86 | 95 | 150 | 162 |

C: crystalline, A: amorphous, N: non-transparent, T: transparent, Tm: melting point

The cycloolefin polymer may contain a plurality of repeating units. The resin material may also contain a plurality of cycloolefin polymers. By mixing a plurality of cycloolefin polymers having different glass transition temperatures (Tg), Tg can be adjusted. A cycloolefin polymer used in one embodiment is obtained by mixing cycloolefin polymers having any of the repeating units A-E, and the Tg is 160° C. This cycloolefin polymer mainly contains a cycloolefin polymer having the repeating unit E.

The cycloolefin polymer represented by the above formula includes carbon atoms and hydrogen atoms. A cycloolefin polymer according to one embodiment is a chemically stable substance. The weight-average molecular weight of the cycloolefin polymer is not particularly limited. In one embodiment, the weight-average molecular weight of the cycloolefin polymer is 1×10⁴ or more and 1×10⁶ or less.

The shape of the resin article 110 is not particularly limited, and may be suitably selected, depending on the application. The thickness of the resin article 110 is not particularly limited, and in one embodiment, is 5.0 μm or more and 1.0 mm or less in order to provide sufficient strength and cause it to be easy to roll up.

The resin article 110 has the recessed portion 140. As described below, the conductor 520 is provided in the recessed portion 140. The shape and position of the recessed portion 140 may be suitably selected, depending on the shape of the conductor 520 to be provided. In one embodiment, the recessed portion 140 has an elongated shape. A depth of the recessed portion 140 is not particularly limited, and may, for example, be 0.01 μm or more and 5.0 μm or less. Also, a width of the recessed portion 140 is not particularly limited, and may, for example, be 3.0 μm or more and 100 μm or less.

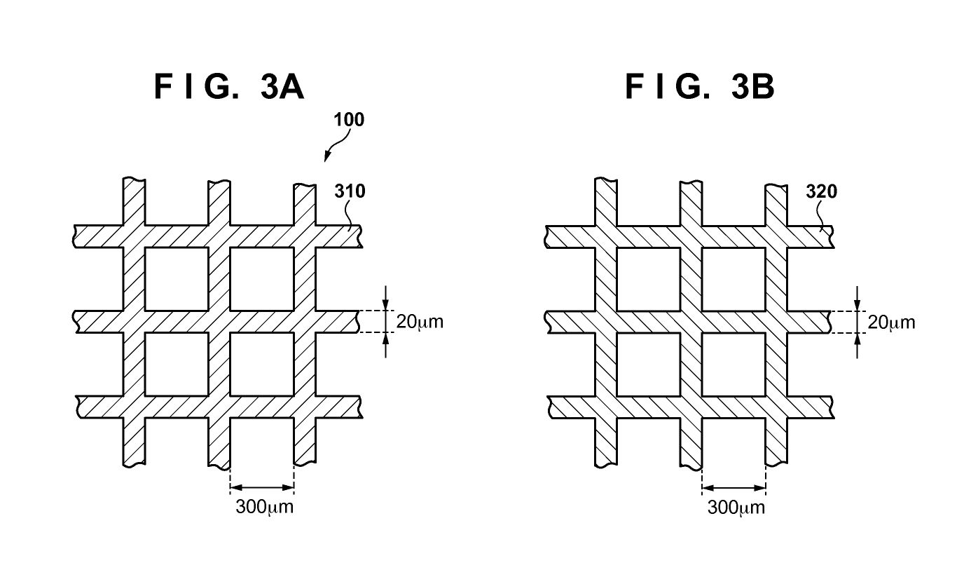

The resin article 110 may have a plurality of the recessed portions 140. For example, in one embodiment, the resin article 110 may have a plurality of the recessed portions 140 which are in parallel with each other. Alternatively, the resin article 110 may have a first plurality of the recessed portions 140 which are in parallel with each other, and a second plurality of the recessed portions 140 which are in parallel with each other, where the first plurality of recessed portions and the second plurality of recessed portion may intersect. For example, as shown in FIG. 3A, the resin article 110 may have the recessed portions 140 which are arranged in a mesh pattern. The mesh pattern may be suitably selected, depending on the application of the conductive film 100. For example, an interval between adjacent ones of the recessed portions 140, that are in parallel with each other, is not particularly limited, and may be 50 μm or more and 1.0 mm or less. By increasing the interval, the light transmittance in the presence of the conductor 520 is improved. By decreasing the interval, the resistance is easily sufficiently reduced.

(Conductor)

The conductor 520 is provided on a surface of the resin article 110. A material for the conductor 520 is not particularly limited. Any material that can be formed into the conductor 520 by electroless plating and can conduct electricity may be employed. Examples of the conductor material include copper, nickel, and the like, or alloys such as copper-nickel and the like. A transparent material, such as ZnO or the like, may also be employed. A thickness of the conductor 520 may be increased by electroplating after electroless plating. A material for increasing the thickness by electroplating is not particularly limited. Any material that can be used in electroplating and can conduct electricity may be employed. Examples of such a material include copper, nickel, copper-nickel alloy, zinc oxide, zinc, silver, cadmium, iron, cobalt, chromium, nickel-chromium alloy, tin, tin-lead alloy, tin-silver alloy, tin-bismuth alloy, tin-copper alloy, gold, platinum, rhodium, palladium, palladium-nickel alloy, and the like. When a material which can conduct electricity is employed, a displacement plating process of silver or the like may be added when necessary.

The conductor 520 may have any shape, e.g., a fine conductive line-like shape. The conductor 520 is arranged on the resin article 110 according to a predetermined pattern. The predetermined pattern may, for example, be a mesh pattern. In this case, the mesh pattern is not particularly limited. Alternatively, a pattern of a stripe, square, rectangle, rhombus, honeycomb, curve, or indefinite shape may be employed.

In this embodiment, the conductor 520 is formed in the recessed portion 140 of the resin article 110. The conductor 520 may cover substantially all the surface of the recessed portion 140. In one embodiment, a width of the conductor 520 corresponds to a width of the recessed portion 140 of the resin article 110, and is, for example, 3 μm or more and 100 μm or less. In one embodiment in which the conductor 520 having a linear shape is arranged in a mesh pattern, the interval between adjacent conductive lines which are in parallel with each other, i.e., the width of a void of the conductive film, is not particularly limited, and may be 50 μm or more and 1.0 mm or less. In one embodiment, the percentage of a portion of the resin article 110 in which the conductor 520 is not provided, i.e., the aperture ratio, is 60% or more. The thickness of the conductor 520 is not particularly limited, and is within the range of 0.02 μm or more and 100 μm or less in one embodiment, or the range of 5 μm or more and 20 μm or less in another embodiment. By decreasing the thickness, the line width of the pattern can be easily reduced. By increasing the thickness, sufficient electromagnetic wave shield capability or sufficiently low resistance can be provided.

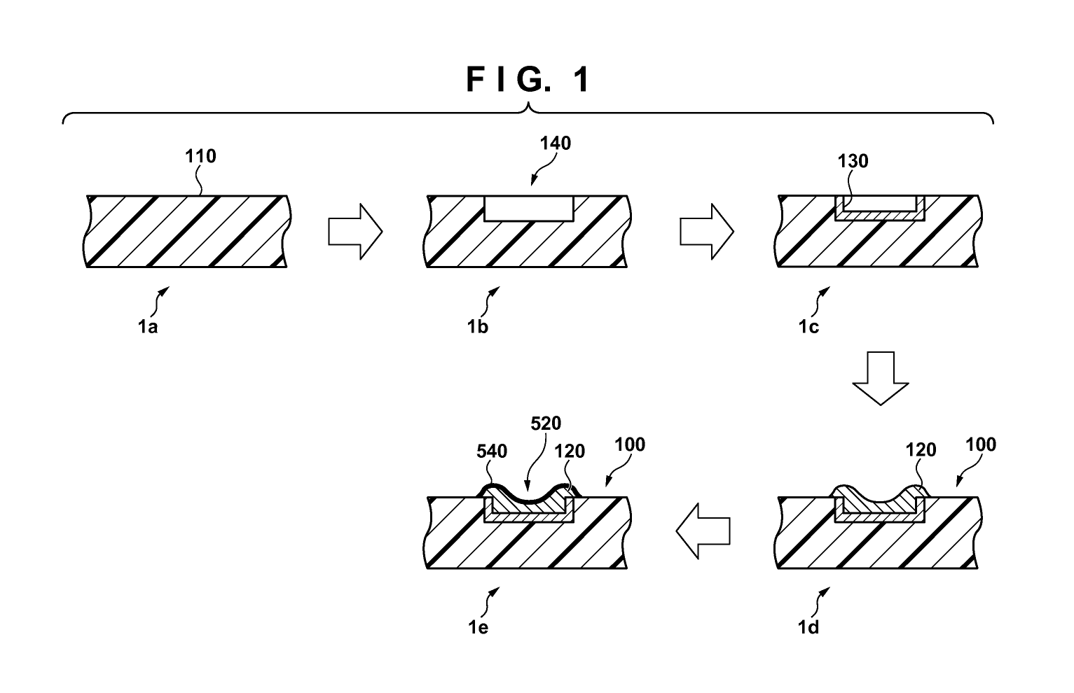

In particular, when the conductive film 100 is a transparent conductive film having a metal mesh pattern, the transparency of the conductive film 100 can be improved by decreasing the width of the conductor 520. However, if the width of the conductor 520 is decreased, the electrical resistance of the conductor 520 increases, which is a problem. If the thickness of the conductor 520 is increased, the electrical resistance of the conductor 520 can be decreased. However, if the conductor 520 is formed on a flat and even surface of the resin article 110, then when the thickness of the conductor 520 is increased, the conductor 520 spreads not only in the vertical direction but also in the horizontal direction due to isotropic growth. Therefore, the actual pattern of the conductor 520 significantly differs from the desired conductor pattern. Also, the aperture ratio is likely to decrease, leading to decrease in the transparency. Moreover, the conductor 520 may come off. In this embodiment, the conductor 520 is formed in the recessed portion 140 of the resin article, and therefore, the horizontal spread can be reduced by appropriately increasing the depth of the recessed portion 140 and thereby decreasing the width of the conductor 520 and increasing the thickness of the conductor 520 as shown in FIG. 1. Also, the coming off of the conductor 520 from the resin article 110 can be reduced. Here, the width of the conductor 520 refers to a width of the conductor 520 along the surface of the resin article 110. The thickness of the conductor 520 refers to a thickness of the conductor 520 along the thickness direction of the resin article 110.

(Black Layer)

When the conductive film 100 is a transparent conductive film having a metal mesh pattern, the conductor 520 reflects light because the conductor 520 typically has a high light reflectance. In this case, the visibility of the transparent conductive film 100 is likely to be impaired. Therefore, in one embodiment, a black layer 540 having a low light reflectance is provided on the transparent conductive film 100. The black layer 540 can be used to reduce the light reflectance, thereby increasing the visibility.

There are the following example layer configurations for improving the visibility.

1. A black conductor 520 is formed to serve as the black layer 540. For example, as described below, the electroless plating layer 130 which also serves as the black layer 540 may be formed in the recessed portion 140 (one-layer configuration).

2. The black layer 540 is formed on the conductor 520. For example, as described below, the electroless plating layer 130 may be formed in the recessed portion 140, and the black layer 540 may be formed on the electroless plating layer 130 (two-layer configuration). Alternatively, the electroless plating layer 130 may be formed in the recessed portion 140, the electroplating layer 120 may be formed on the electroless plating layer 130, and the black layer 540 may be formed on the electroplating layer 120 (three-layer configuration).

From these configurations, a suitable one may be selected, depending on required performance, such as conductivity, cost, adhesiveness, or the like. In any case, the black layer 540 is formed at an uppermost portion of the conductive film.

A material for the black layer 540 is not particularly limited, and may be either an organic material or an inorganic material. In one embodiment, the black layer 540 has a total luminous reflectance (JIS K7375: 2008) of 10% or less. Such a black layer 540 may, for example, be a black plating layer. The black plating layer may be formed by performing black plating which provides a black plating layer, such as electroless black nickel plating. A kit for performing electroless black nickel plating may, for example, be KANIBLACK (registered trademark, manufactured by Japan Kanigen Co., Ltd.), or the like.

The thickness of the black layer 540 is not particularly limited, and may be suitably selected, depending on the application of the conductive film. The thickness of the black layer 540 is not particularly limited, and may, for example, be 0.10 μm or more and 5.0 μm or less.

(Method for Manufacturing Conductive Film)

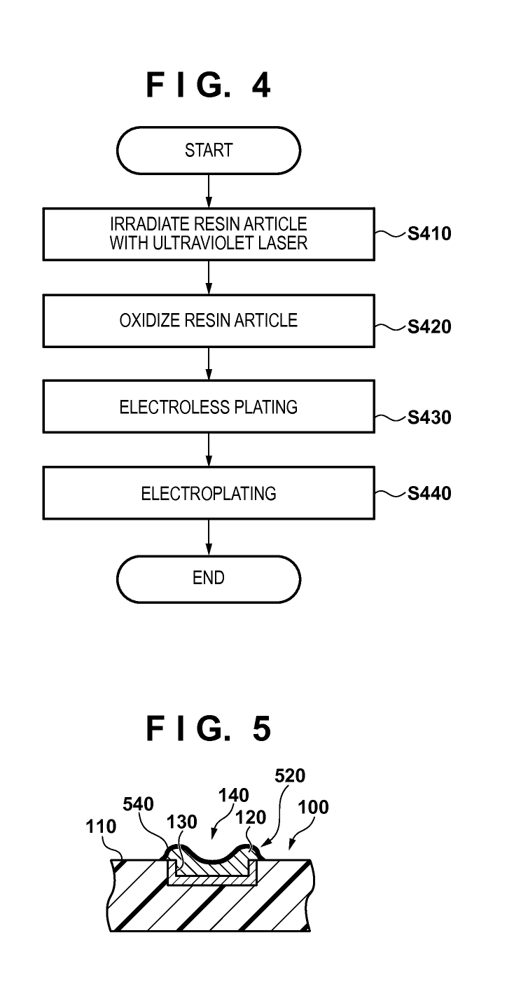

A method for manufacturing the conductive film 100 of this embodiment is not particularly limited, and may, for example, be a suitable combination of photolithography, vapor deposition, plating, and the like. An example method for manufacturing the conductive film 100 of this embodiment (hereinafter referred to as “the manufacturing method of this embodiment”) will be described. The manufacturing method of this embodiment has an irradiation step, an oxidation step, and a formation step. These steps will now be described in detail with reference to a flowchart shown in FIG. 4.

(Irradiation Step)

In the irradiation step (S410), a portion of the resin article 110 in which the conductor 520 is to be formed is irradiated with an ultraviolet laser. A portion 1a of FIG. 1 is a cross-sectional view of the resin article 110. FIG. 3A is a top view of the resin article 110. As shown in FIG. 3A, a portion 310 in which the conductor 520 is to be formed is irradiated with an ultraviolet laser, so that, as shown in a portion 1b of FIG. 1, the portion of the resin article 110 irradiated with an ultraviolet laser is modified and formed into the recessed portion 140.

Specifically, ultraviolet light irradiation decomposes oxygen in an atmosphere to generate ozone. Moreover, active oxygen is generated during decomposition of ozone. Also, a bond in a molecule included in the resin article 110 is cut at a surface of the resin article 110. In this case, the molecule included in the resin article 110 reacts with the active oxygen, so that the surface of the resin article 110 is oxidized, i.e., the C—O bond, C═O bond, C(═O)—O bond (the backbone portion of a carboxyl group), and the like are formed. Such a hydrophilic group increases chemical adsorption capability between the resin article 110 and the electroless plating layer 130. An embrittled portion caused by the oxidation of the resin surface is washed off in a preprocess step for plating, so that a fine rough surface is formed on the resin surface, and therefore, physical adsorption capability with respect to the plating layer is increased due to the anchor effect. Moreover, the modified portion can be caused to selectively adsorb a catalyst ion during electroless plating.

The energy of a photon having a specific wavelength is represented by:

E=Nhc/λ (KJ·mol⁻¹)

N=6.022×10²³ mol⁻² (Avogadro's number)

h=6.626×10⁻³⁷ KJ·s (Planck constant)

c=2.988×10⁸ m·s⁻¹ (the speed of light)

λ=the wavelength of light (nm)

Here, the bond energy of an oxygen molecule is 490.4 KJ·mol⁻¹. According to the photon energy expression, the bond energy is equivalent to the energy of light having a wavelength of about 243 nm. This indicates that an oxygen molecule in an atmosphere absorbs ultraviolet light having a wavelength of 243 nm or less to decompose. As a result, ozone O₃ is generated. Moreover, active oxygen is generated during decomposition of ozone. At this time, if ultraviolet light having a wavelength of 310 nm or less is present, ozone is efficiently decomposed to generate active oxygen. Moreover, ozone is most efficiently decomposed by ultraviolet light having a wavelength of 254 nm.

O₂+hν(243 nm or less)→O(3P)+O(3P)

O₂+O(3P)→O₃(ozone)

O₃+hν(310 nm or less)→O₂+O(1D)(active oxygen)
O (3P): ground-state oxygen atom
O (1D): excited oxygen atom (active oxygen)

The type and laser wavelength of the ultraviolet laser are not particularly limited, and may be selected to promote the modification of the surface of the resin article 110. In one embodiment, the wavelength of the ultraviolet laser is 243 nm or less. The ultraviolet laser having a wavelength of 243 nm or less promotes the modification of the surface of the resin article 110 to a greater extent.

Ultraviolet laser has higher-density energy than that of ultraviolet light from an ultraviolet lamp. Therefore, a certain degree of surface modification can be quickly achieved. When such quick irradiation is performed, the thermal expansion of the resin article 110 is substantially prevented, and therefore, the portion of the resin article 110 in which the conductor is to be formed can be modified with high precision. In one embodiment, a pulsed ultraviolet laser which can easily provide a high energy density is employed. In one embodiment, the energy density of ultraviolet light for irradiation in the irradiation step at a main wavelength is 1.0×10⁵ W/cm² or more. The upper limit of the energy density is not particularly limited, and may, for example, be 1.0×10¹⁵ W/cm² or less. When a single-wavelength laser is used as the ultraviolet laser, the wavelength of the laser is the main wavelength.

In one embodiment, an excimer laser is used as the ultraviolet laser. The excimer laser is a type of gas laser. Specifically, a high voltage is instantaneously applied to a mixture of an inert gas and a halogen gas to create an excited state, thereby causing pulse oscillation having high power. By using an excimer laser, the surface of the resin article 110 can be modified as quickly as possible in order to reduce the thermal expansion.

The wavelength of an excimer laser is changed by changing the mixture of an inert gas and a halogen gas for generating the laser. A relationship between the gas combination and the laser wavelength is the following.
F₂ excimer laser: wavelength 157 nm
ArF excimer laser: wavelength 193 nm
KrCl excimer laser: wavelength 222 nm

In one embodiment, the ArF excimer laser is used as the ultraviolet laser. The ArF excimer laser has a relatively short wavelength, and therefore, more efficiently modifies the surface of the resin article 110. The ArF excimer laser is less absorbed by the air than the F₂ excimer laser, and therefore, is easy to handle.

In one embodiment, the portion of the resin article 110 in which a conductor is to be formed is irradiated with the excimer laser in a pulsed fashion. The quick irradiation with pulsed laser can reduce the thermal expansion of the resin article 110. In one embodiment, the pulse width is 10 ns or more and 100 ns or less. A pulsed laser having high intensity is obtained by causing laser light to reciprocate in an optical resonator and then extracting laser light after a certain period of time has elapsed.

The irradiation amount and number of pulses of the laser may be suitably selected, depending on the type of the resin article 110 and the depth of the recessed portion 140 which is to be formed. In one embodiment, a laser having an energy density per pulse of 50 mJ/cm² or more and 5000 mJ/cm² or less is used for the irradiation. In another embodiment, a laser having an energy density per pulse of 80 mJ/cm² or more and 2000 mJ/cm² or less is used for the irradiation. In one embodiment, the laser irradiation is performed so that the cumulative irradiation amount is 1000 mJ/cm² or more and 20000 mJ/cm² or less. In another embodiment, the laser irradiation is performed so that the cumulative irradiation amount is 100 mJ/cm² or more and 50000 mJ/cm² or less.

In one embodiment, a laser beam from the excimer laser has, for example, a rectangular beam shape of about 20×10 mm, in which the shape of the electric discharge region is reflected. Because the beam is thick and the pulse energy is high, a relatively large area can be simultaneously treated by a relatively high irradiation intensity using the excimer laser. Also, by using a suitable lens, the shape of the laser beam can be changed into a linear shape. By using a condenser lens, a spot-shaped beam can be used for the irradiation.

In one embodiment, the resin article 110 is irradiated with the ultraviolet laser in an atmosphere containing at least one of oxygen and ozone or in an atmosphere containing oxygen or ozone. Specifically, for example, the resin article 110 may be irradiated with the ultraviolet laser in the atmosphere. In another embodiment, in order to promote the modification to a greater extent, the irradiation is performed in an atmosphere containing ozone.

On the other hand, in another embodiment, the resin article 110 may, for example, be irradiated with the ultraviolet light in an atmospheres of other gases, such as an atmosphere of an amine compound gas (e.g., ammonia), an atmosphere of an amide compound gas, and the like. When the irradiation is performed in an atmosphere of an amine compound gas or an atmosphere of an amide compound gas, the surface of the resin article 110 can be oxidized, i.e., a bond containing a nitrogen atom can be generated in the surface of the resin article 110. Specifically, the surface of the resin article 110 is modified to contain nitrogen atoms, so that the capability to adsorb the plating layer is improved, and therefore, selective plating can be performed on the irradiated portion. When an object to be processed is separated from the atmospheric pressure and the atmosphere, and is modified using ultraviolet light while the pressure is changed or a compound gas is introduced, a wavelength suitable for the reaction can be appropriately selected. On the other hand, if ultraviolet light having a wavelength of 243 nm or less is used for the irradiation in the atmosphere, which contains oxygen, the modification can be advantageously performed at low cost.

For example, the resin article 110 may be scanned using a laser beam so that each portion of the resin article 110 in which a conductor is to be formed is irradiated with the laser beam a predetermined number of times. Thus, the portion of the resin article 110 in which a conductor is to be formed can be irradiated with the ultraviolet laser. For example, if a photomask, metal mask, or the like corresponding to the shape of the conductor is inserted into the optical system for the ultraviolet laser, the portion of the resin article 110 in which a conductor is to be formed can be irradiated with the ultraviolet laser. Furthermore, if a photomask, metal mask, or the like corresponding to the shape of the electroless plating layer 130 is provided on the resin article 110, and scanning is performed using a linear beam, the resin article 110 having a large area can be efficiently modified.

Even when the resin article 110 has a three-dimensional shape, a mask having a desired pattern may be fitted to the resin article 110, which may then be irradiated with the ultraviolet laser through the mask. In one embodiment, if a metal plate having an opening corresponding to a desired pattern may be used as a mask, and the metal plate is folded to fit to the resin article 110 having a three-dimensional shape, the three-dimensional resin article 110 can be selectively irradiated with the ultraviolet laser. Alternatively, the portion of the resin article 110 in which the electroless plating layer 130 is to be formed may be irradiated with the ultraviolet laser while being scanned according to a desired pattern.

If the resin article 110 is irradiated with the laser, the recessed portion 140 is formed at the laser irradiated portion. Specifically, a surface of the resin article 110 at the laser irradiated portion is recessed with respect to the surface of the resin article 110 adjacent to the irradiated portion. The depth of the recessed portion 140 can be controlled by changing the irradiation amount of the laser. Specifically, the more the energy density of the laser, or the more the number of pulses, the greater the depth of the recessed portion 140. In a plating step described below, the conductor 520 is formed in the recessed portion 140. In other words, in the conductive film 100 of this embodiment, the conductor 520 is buried in the resin article 110. Therefore, compared to a conductive film which is obtained by forming a conductor on a flat and even resin article, the conductor 520 does not easily come off the conductive film 100 of this embodiment. Also, the conductor 520 is buried in the resin article 110, and therefore, it is easy to reduce the thickness of the conductive film 100. Also, even when the thickness of the plating layer is increased by electroless plating or electroplating in order to reduce the resistivity of the conductor 520, the growth in the horizontal direction can be reduced by increasing the depth of the recessed portion 140 as appropriate. Therefore, the aperture ratio can be maintained, thereby preventing impairment of the transparency.

(Oxidation Step)

After the irradiation step, performed is the oxidation step (S420) of performing an oxidation process on the resin article 110. Specifically, the oxidation process is performed on a region of the resin article 110 including a portion in which the conductor 520 is to be formed.

Although the surface of the resin article 110 is modified by the ultraviolet laser irradiation, the modified layer is removed by the ablation effect of the ultraviolet laser, and therefore, there is a limit on the amount of the modification. Therefore, the modification is not sufficient for deposition of plating. Therefore, in the oxidation step, the oxidation process is performed on the region including the portion which has been irradiated with the ultraviolet laser, whereby the surface of the resin article 110 is modified to a greater extent. In this case, the oxidation process is performed so that, for the portion which has been irradiated with the laser, the amount of the surface modification is increased so that plating is to be deposited, and for the portion which has not been irradiated with the laser, the amount of the surface modification is small so that plating is not to be deposited. The ablation refers to removal of a material, for example, by evaporating the material locally on the material surface by irradiating the material with a strong laser and thereby increasing the temperature of the material locally to a high temperature.

Specific examples of the oxidation process include a plasma process, an oxidation process using a chemical agent, an oxidation process by ultraviolet light irradiation, and the like. A method of using ultraviolet light, which can be easily performed, will now be described. Specifically, as in the irradiation step, the resin article 110 is modified to a greater extent by ultraviolet light irradiation in an atmosphere containing oxygen, ozone, an amine compound gas, an amid compound gas, or the like. Here, a region including a portion in which the conductor 520 is to be formed is irradiated with ultraviolet light. In particular, in one embodiment, a region which includes the portion in which the conductor 520 is to be formed and is larger than a desired portion is irradiated with ultraviolet light. In other words, in the oxidation step, it is not essential to limit the portion irradiated with ultraviolet light using a mask or the like. Also, even if the resin article 110 is expanded due to heat in the oxidation step, then when the temperature returns to ordinary temperature, the modification position at which plating is to be deposited is not displaced, because a mask is not employed.

In one embodiment, ultraviolet light having a wavelength of 243 nm or less is used for the irradiation. More specifically, ultraviolet light having a main wavelength of 243 nm or less is used for the irradiation. Unless otherwise specified, the irradiation amount and irradiation intensity of the ultraviolet light hereinafter refer to those of the main wavelength. As used herein, the main wavelength refers to a wavelength having a highest intensity in the region of 243 nm or less. Specifically, in the case of a low-pressure mercury lamp, the main wavelength is 185 nm.

When the wavelength is 243 nm or less, the modification of the surface of the resin article 110 is promoted to a greater extent. Also, when the wavelength of the ultraviolet light is 243 nm or less, the modification can be performed by utilizing oxygen in the atmosphere under the atmospheric pressure, and therefore, the modification can be performed at low cost. Such ultraviolet light can be obtained using an ultraviolet lamp or ultraviolet LED which continuously emits ultraviolet light, or the like, and therefore, a large area can be simultaneously subjected to the oxidation process. In the irradiation step according to one embodiment, the ultraviolet laser is controlled so that the irradiation time is short. In the oxidation step, it is not necessary to limit the irradiation time to a short time. Therefore, the energy density of ultraviolet light used in the oxidation step may be lower than the energy density of ultraviolet light used in the irradiation step.

Examples of the ultraviolet lamp include a low-pressure mercury lamp, excimer lamp, and the like. The low-pressure mercury lamp can emit ultraviolet light having a wavelength of 185 nm and 254 nm. For reference, example excimer lamps which can be used in the atmosphere are the following. As an excimer lamp, a Xe₂ excimer lamp is typically used.
Xe₂ excimer lamp: wavelength 172 nm
KrBr excimer lamp: wavelength 206 nm
KrCl excimer lamp: wavelength 222 nm

In the oxidation step of this embodiment, the portion in which the conductor 520 is to be formed is already modified using the ultraviolet laser. Therefore, the irradiation time of the ultraviolet lamp in the oxidation step is shorter than when the resin article is modified without using the ultraviolet laser.

When the resin article 110 is irradiated with ultraviolet light from an ultraviolet lamp or the like, the ultraviolet light irradiation is controlled to achieve a desired irradiation amount. The irradiation amount can be controlled by changing the irradiation time. The irradiation amount can also be controlled by changing the power, number, irradiation distance, or the like of ultraviolet lamps. A specific irradiation amount will be described below.

However, conditions for deposition of plating may vary depending on the type of the plating solution, the type of the substrate, the amount of contamination on the substrate surface, the concentration, temperature, pH, and aging of the plating solution, the fluctuation of the power of the ultraviolet lamp, the defocus of the excimer laser, or the like. In this case, based on the above numerical values, the irradiation amount of the ultraviolet lamp may be suitably determined so that plating is selectively deposited on the laser irradiated portion.

(Irradiation Amount)

The irradiation amount of the ultraviolet laser in the irradiation step, and the irradiation amount of the ultraviolet light in the oxidation step, are adjusted so that plating is deposited on the portion which has been irradiated with the ultraviolet laser, and plating is not deposited on the portion which has not been irradiated with the ultraviolet laser. To achieve these deposition conditions, for example, in one embodiment in which an olefin resin, such as a cycloolefin polymer, is employed, the irradiation amount of the ultraviolet laser is adjusted so that, for the laser irradiated portion, the abundance ratio of oxygen atoms in the surface of the resin article 110 after the irradiation step is 3.0% or more or 3.8% or more. Note that the abundance ratio of hydrogen atoms is ignored and is not taken into account in the calculation.

In one embodiment, in order to allow for deposition of plating, the irradiation amount of the ultraviolet light is adjusted so that the abundance ratio of oxygen atoms after the oxidation step is 18% or more or 20.1% or more in the portion which has been irradiated with the laser. If plating is deposited, the abundance ratio of oxygen atoms does not have an upper limit. Also, in order not to allow for deposition of plating, the irradiation amount of the ultraviolet light is adjusted so that the abundance ratio of oxygen atoms after the oxidation step is 15% or less or 12.6% or less in the portion which has not been irradiated with the laser. If plating is not deposited, the abundance ratio of oxygen atoms does not have a lower limit.

As used herein, the abundance ratio of oxygen atoms refers to the abundance ratio (atom %) of oxygen atoms with respect to all atoms, that is calculated by XPS measurement. Note that hydrogen atoms cannot be detected by XPS measurement, and therefore, the number of hydrogen atoms is not taken into account in the calculation. The abundance ratio of oxygen atoms may vary to some extent, depending on measurement conditions, detection error occurring in each instrument, or the like.

In one embodiment, the irradiation amount of the ultraviolet light in the oxidation step is adjusted to 400 mJ/cm² or less at a wavelength of 185 nm so that plating is not deposited on the portion which has not been irradiated with the laser. Unless otherwise specified, the irradiation amount and irradiation intensity of the ultraviolet light refer to those at a wavelength 185 nm. In one embodiment in which the irradiation intensity of ultraviolet light from an ultraviolet lamp or the like is 1.35 mW/cm², the irradiation time of the ultraviolet light from the ultraviolet lamp or the like in the oxidation step is adjusted to 5 min or less so that plating is not deposited on the portion which has not been irradiated with the laser.

The irradiation amount of the ultraviolet light from the ultraviolet lamp or the like can be set as follows so that plating is deposited on the portion which has been irradiated with the laser. In one embodiment in which the abundance ratio of oxygen atoms after the irradiation step is 6.5% or more or 7.1% or more in the portion which has been irradiated with the ultraviolet laser, the irradiation amount of the ultraviolet light in the oxidation step is set to 65 mJ/cm² or more or 81 mJ/cm² or more. In one embodiment in which the irradiation intensity of the ultraviolet light from the ultraviolet lamp or the like is 1.35 mW/cm², the irradiation time of the ultraviolet light from the ultraviolet lamp or the like in the oxidation step is set to 0.8 min or more or 1 min or more. For example, when a laser having an energy density of 80 mJ/cm² or more and 150 mJ/cm² or less, or about 100 mJ/cm², is used in the laser irradiation step, an irradiation amount of ultraviolet light which satisfies the above conditions can be used for the irradiation in the oxidation step.

In one embodiment in which the abundance ratio of oxygen atoms after the irradiation step is 3.0% or more or 3.8% or more in the portion which has been irradiated with the ultraviolet laser, the irradiation amount of the ultraviolet light in the oxidation step is set to 200 mJ/cm² or more or 243 mJ/cm² or more. In one embodiment in which the irradiation intensity of the ultraviolet light from the ultraviolet lamp or the like is 1.35 mW/cm², the irradiation time of the ultraviolet light from the ultraviolet lamp or the like in the oxidation step is set to 2.5 min or more or 3 min or more. For example, when a laser having an energy density of 800 mJ/cm² or more and 5000 mJ/cm² or less, 1000 mJ/cm² or more and 2000 mJ/cm² or less, 800 mJ/cm² or more and 2000 mJ/cm² or less, or 1000 mJ/cm² is used in the irradiation step, an irradiation amount of ultraviolet light which satisfies the above conditions can be used for the irradiation in the oxidation step.

In one embodiment, if the ultraviolet laser irradiation is performed so that the abundance ratio of oxygen atoms after the irradiation step is 6.5% or more or 7.1% or more in the portion which has been irradiated with the laser, the irradiation time of the ultraviolet light can be reduced in the oxidation step following the irradiation step. In one embodiment, if a laser having an energy density of 80 mJ/cm² or more and 150 mJ/cm² or less, or 100 mJ/cm² is used, the irradiation time of the ultraviolet light can be reduced in the oxidation step following the irradiation step.

The abundance ratio of oxygen atoms after the irradiation step in the portion which has been irradiated with the laser can be controlled by adjusting the energy density of the laser. Specifically, if the energy density is within the range of 100 mJ/cm² to 2000 mJ/cm², or specifically, within the range of 100 mJ/cm² to 5000 mJ/cm², then when the pulse irradiation is performed so that the cumulative irradiation amount is the same, the abundance ratio of oxygen atoms tends to decrease with an increase in the energy density. Conversely, when the cumulative irradiation amount is the same, the abundance ratio of oxygen atoms tends to be greater when the irradiation is performed a large number of times using a low energy density than when the irradiation is performed a small number of times using a high energy density. The abundance ratio of oxygen atoms after the oxidation step can be controlled by adjusting the irradiation amount of the ultraviolet light. Specifically, the abundance ratio of oxygen atoms tends to increase with an increase in the irradiation amount of the ultraviolet light.

The above irradiation amount is particularly effective in performing electroless copper-nickel plating in the plating step. However, even when a different plating solution or the like is used, the irradiation amounts in the irradiation step and oxidation step can be adjusted based on the above findings. Specifically, the irradiation amount can be adjusted, depending on the compositions of the resin article and plating solution, so that plating is deposited on the portion which has been irradiated with the ultraviolet laser, and plating is not deposited on the portion which has not been irradiated with the ultraviolet laser.

(Formation Step)

In the formation step, the conductor 520 is formed in the portion of the resin article 110 which has been irradiated with the ultraviolet laser. The formation step includes an electroless plating step (S430) of performing electroless plating on the resin article 110 after the oxidation step.

As shown in a portion 1c of FIG. 1, in the electroless plating step, electroless plating is performed on the resin article 110 so that the electroless plating layer 130 is selectively deposited on the ultraviolet laser irradiated portion, i.e., the recessed portion 140, of the resin article 110. According to this embodiment, it is not essential to perform patterning on the plating layer using a technique, such as etching or the like, after the formation of the plating layer. The specific electroless plating technique is not particularly limited. As described above, the types of the electroless plating layer 130 and the electroplating layer 120 are not particularly limited, and may be a metal layer, and may be formed from a material, such as copper, nickel, zinc oxide, or the like. Examples of electroless plating which can be employed include electroless plating using a formalin-based electroless plating bath, electroless plating using, as a reducing agent, hypophosphorous acid, which has a slow deposition rate and is easy to handle, and the like. The electroless plating layer 130 may be formed using a fast electroless plating technique in order to form a thicker plating layer. Other specific examples of electroless plating include electroless nickel plating, electroless copper plating, electroless copper-nickel plating, and the like.

The irradiation step and the oxidation step cause nanometer-scale unevenness on the surface of the portion of the resin article 110 in which the conductor 520 is to be formed. The unevenness improves the adhesiveness between the electroless plating layer 130 deposited and the resin article 110 due to the anchor effect, and therefore, the coming off of the conductor 520 from the resin article 110 is reduced.

As described below, the electroplating layer 120 formed on the electroless plating layer 130 thus deposited by plating has a lower electrical resistance than that of, for example, a conductor obtained by sintering nanoparticle metal paste, and therefore, is advantageous when it is used as a conductor. Also, unlike the case where nanoparticle metal paste is sintered, it is not necessary to subject the resin article 110 to high temperature, and therefore, in this embodiment, the resin article 110 having low heat resistance can be used.

In one embodiment, electroless plating can be performed as follows.

1. (Alkali Process) The resin article 110 is immersed in an alkaline solution for degreasing, whereby the hydrophilicity is increased. The alkaline solution may, for example, be an aqueous sodium hydroxide solution or the like.

2. (Conditioner Process) The resin article 110 is immersed in a solution containing a binder for the resin article 110 and a catalyst ion. The binder may, for example, be a cationic polymer or the like.

3. (Activator Process) The resin article 110 is immersed in a solution containing a catalyst ion. The catalyst ion may, for example, be a palladium complex such as a hydrochloric acidic palladium complex, or the like.

4. (Accelerator Process) The resin article 110 is immersed in a solution containing a reducing agent so that a catalyst ion is reduced and deposited. Examples of the reducing agent include hydrogen gas, dimethyl amine borane, sodium borohydride, and the like.

5. (Electroless Plating Process) The electroless plating layer 130 is deposited on the deposited catalyst.

Electroless plating according to such a technique may be performed using, for example, an electroless plating solution set, such as a Cu—Ni plating solution set “AISL,” manufactured by JCU CORPORATION, or the like.

In another embodiment, a palladium-basic amino acid complex, which is likely to adhere to the modified resin article 110, can be used as the catalyst ion. In this case, it is not essential to immerse the resin article 110 in the binder solution to increase the affinity between the resin article 110 and the catalyst ion. The palladium-basic amino acid complex is a complex of a palladium ion and a basic amino acid. The palladium ion is not particularly limited. A divalent palladium ion is commonly used as the palladium ion. The basic amino acid may be either a naturally-occurring amino acid or an artificial amino acid. In one embodiment, the amino acid is an α-amino acid. The basic amino acid may, for example, be an amino acid having, at a side chain thereof, a basic substituent such as an amino group, guanidyl group, or the like. Examples of the basic amino acid include lysine, arginine, ornithine, and the like.

A specific example of the palladium-basic amino acid complex is represented by:

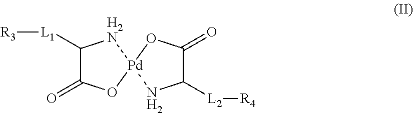

where L₁ and L₂ each independently represent an alkylene group having 1-10 carbon atoms, and R₃ and R₄ each independently represent an amino group or a guanidyl group. Examples of the alkylene group having 1-10 carbon atoms include linear alkylene groups, such as methylene, 1,2-ethanediyl, 1,3-propanediyl, n-butane-1,4-diyl, and the like. Although, in Formula (II), the two amino groups are located trans to each other, the two amino groups may be located cis to each other. The palladium-basic amino acid complex may be a mixture of cis and trans isomers.

The conductor 520 may be formed only by electroless plating. In other words, the electroless plating layer 130 may serve as the conductor 520. However, the electroless plating layer 130 formed by electroless plating is thin in many cases. Therefore, in the formation step, in order to reduce the resistance of the conductor 520, an electroplating step (S430) of performing electroplating on the resin article 110 may be performed after the electroless plating step. As shown in a portion 1d of FIG. 1, in the electroplating step, the electroplating layer 120 is additionally deposited on the electroless plating layer 130 by electroplating. By using electroplating, a thick plating layer can be easily deposited compared to electroless plating. In this case, the electroplating layer 120, or both the electroless plating layer 130 and the electroplating layer 120, serve as the conductor 520. The specific electroplating technique is not particularly limited. For example, nickel plating, copper plating, copper-nickel plating, or the like, may be performed.

In this embodiment, the electroless plating layer 130 is formed in the recessed portion 140 of the resin article 110. Therefore, as shown in the portion 1d of FIG. 1, when electroplating is performed on the electroless plating layer 130, the electroplating layer 120 formed tends to be limited to the recessed portion 140 of the resin article 110 and is less likely to spread over the surface of the resin article 110. In other words, even when the thickness of the conductor 520 is increased due to electroplating, the width of the conductor 520 is less likely to increase. Thus, in this embodiment, by combining electroless plating and electroplating, the conductor 520 which has a low electrical resistance and a desired pattern can be formed with high precision.

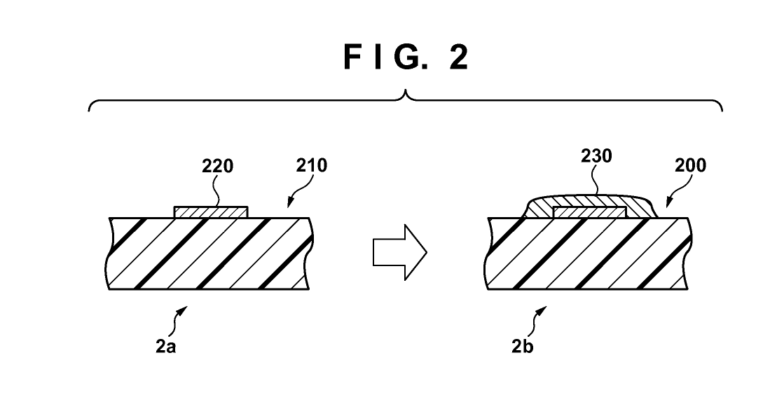

On the other hand, when a pattern of plating layer 220 is formed on a flat and even surface of a resin film 210, and electroplating is performed on the plating layer 220 as shown in a portion 2a of FIG. 2, an electroplating layer 230 is likely to spread over the surface of the resin film 210 as shown in a portion 2b of FIG. 2. Therefore, if the thickness of the conductor is increased in order to reduce the electrical resistance, the width of the conductor also increases, and a conductor pattern obtained significantly differs from the pattern of the plating layer 220. In particular, when a transparent conductive film is produced, then if the width of the conductor increases, the optical transparency of the transparent conductive film decreases. On the other hand, according to this embodiment, the width of the conductor 520 can be easily controlled, whereby the conductive film 100 which has high optical transparency, i.e., is transparent, can be manufactured.

In a further embodiment, in the electroless plating step, electroless black plating is performed so that the black layer 540 is formed on the ultraviolet light irradiated portion of the resin article 110. In other words, the electroless plating layer 130 serves as the black layer 540. In this case, the film formation process is here completed.

In a further embodiment, the electroless plating layer 130 is formed in the ultraviolet light irradiated portion of the resin article 110, and electroless black plating is performed on the electroless plating layer 130 to form the black layer 540. In this case, the film formation process is here completed.

In a further embodiment, the electroless plating layer 130 is formed on the ultraviolet light irradiated portion of the resin article 110, and electroplating is performed on the electroless plating layer 130 to form the electroplating layer 120. This electroplating layer serves as the conductor 520. Moreover, electroless black plating is performed on the electroplating layer 120 to form the black layer 540. The conductive film 100 thus obtained is shown in a portion 1e of FIG. 1.

The black plating is not particularly limited. Any black plating that can be used to form a black plating layer may be employed. For example, electroless black nickel plating or the like may be employed. Electroless black plating may be performed using, for example, an electroless plating solution set, such as an electroless black plating solution set “KANIBLACK (registered trademark),” manufactured by Japan Kanigen Co., Ltd., or the like. Even when the electrical resistance of the black layer 540 is high, then if electroless plating or electroplating is performed to provide a normal metal plating layer in advance, mesh-pattern interconnect lines having low electrical resistance can be formed.

The conductive film 100 thus manufactured has the resin article 110 having a modified portion of the surface which is formed by the ultraviolet laser irradiation and the oxidation process after the ultraviolet laser irradiation. The conductive film 100 also has the electroless plating layer 130 which is provided by plating on the modified portion which has been irradiated with the ultraviolet laser, and the electroless plating layer 130 serves as a conductor. All or a portion of the electroless plating layer 130 which serves as a conductor is buried in the recessed portion 140 formed on the resin article 110.

According to this embodiment, by controlling the laser irradiated area in the irradiation step, the portion in which the conductor 520 is to be formed can be controlled. The ultraviolet laser is highly coherent light which has a uniform phase and high ability to travel in a straight line, unlike light of an ultraviolet lamp which is diffused light, and therefore, allows for high-precision modification. In this embodiment, an ultraviolet laser having a short wavelength is employed, and the irradiation time is considerably short and the irradiated area is limited, and therefore, the resin article 110 undergoes substantially no thermal expansion during the laser irradiation. Therefore, for example, during patterning using a mask, modification deviation which would be caused by a difference in thermal expansion coefficient between the mask and the resin article 110 is not likely to occur. Therefore, the laser irradiated area can be precisely controlled, whereby the pattern formation precision can be improved. Also, as described above, a plating layer is deposited on the recessed portion 140 of the resin article, and therefore, the plating layer is less likely to spread over the surface of the resin article. Thus, according to this embodiment, the conductor 520 having a fine pattern can be easily formed.

According to one embodiment, a fine conductive line having a width of 5 μm or less can be formed. That such a fine conductive line can be formed is advantageous to manufacture of the conductive film 100 having high transparency.

According to the method of this embodiment, the conductive film 100 can be easily manufactured. The conductive film 100 thus produced is advantageous over a transparent conductive film which is produced in a manner similar to that which is used to produce a typical printed wiring board. For example, in a technique of manufacturing a typical printed wiring board, a plating layer is initially formed on an entire surface of a resin substrate using electroless plating or the like. In this case, in order to improve the adhesiveness between the resin substrate and the plating layer, micrometer-scale unevenness is formed on the surface of the resin substrate using a permanganic acid solution, chromic acid solution, or the like. However, when unevenness is formed on the transparent resin article, the optical transparency of the transparent conductive film deteriorates. Instead, a metal layer may be formed on the resin substrate by vapor deposition, which causes a problem with the adhesiveness. Thereafter, the metal layer is patterned to provide a desired pattern. In this case, typical photolithography and etching are performed, and therefore, a large amount of liquid waste is produced.

On the other hand, according to the method of this embodiment, nanometer-scale fine unevenness is formed at an interface between the resin article 110 and the electroless plating layer 130. Therefore, it is expected that the optical transparency be maintained, and the adhesiveness between the resin article 110 and the electroless plating layer 130 be improved. In this regard, the surface roughness Ra of a portion of the surface of the resin article 110 on which the electroless plating layer 130 is not formed, is 10 nm or less in one embodiment, and 5 nm or less in another embodiment. The surface roughness Ra of a portion of the surface of the resin article 110 on which the electroless plating layer 130 is formed is 1.5 nm or more in one embodiment. Similarly, before the electroless plating layer 130 is formed, the surface roughness Ra of a portion of the surface of the resin article 110 on which the electroless plating layer 130 is to be formed is 1.5 nm or more in one embodiment. For example, after the conditioner treatment, the surface roughness Ra of the portion in which the electroless plating layer 130 is to be formed may be 1.5 nm or more.

A transparent electrode may be produced by applying, onto a transparent resin film, a solvent in which a large amount of silver nanowires having a thickness of several nanometers and a length of several tens of micrometers are dispersed. However, in this case, the conductor is not a complete continuum, and contact resistance is present between the nanowires. Therefore, the obtained transparent electrode has a sheet resistance of about 50 Ω/sq. Alternatively, a silver mesh pattern may be produced by applying a silver iodide solution onto a transparent resin film and exposing the solution to light according to a desired pattern. However, grain boundary resistance is present in the silver mesh formed by that technique, and therefore, the obtained transparent electrode has a sheet resistance of about 20 Ω/sq. The method of this embodiment is advantageous because, for example, a sheet resistance of about 0.5 Ω/sq can be achieved in one embodiment in which a copper mesh is provided as the conductor 520.

### Second Embodiment

A plating layer which is similar to a metal layer has gloss peculiar to metal. Therefore, if a pattern of plating layer which is similar to a fine metal line is formed on a transparent resin base, external light is strongly reflected at some viewing angle due to the gloss peculiar to metal, and therefore, visibility through the obtained resin article may decrease. This problem is significant, particularly when the obtained resin article is used in a display device, such as a touch panel or the like.

In a second embodiment, for a resin article in which a pattern of metal layer or plating layer is formed on a transparent resin base, visibility through the resin article is improved. Specifically, when a resin article with plating layer which has a resin article and a plating layer provided on a surface of the resin article is produced, the plating layer is formed to exhibit a black color, whereby a decrease in visibility due to the gloss peculiar to metal can be reduced.

(Plating layer Exhibiting Black Color)

An example method of forming a plating layer exhibiting a black color is the following.

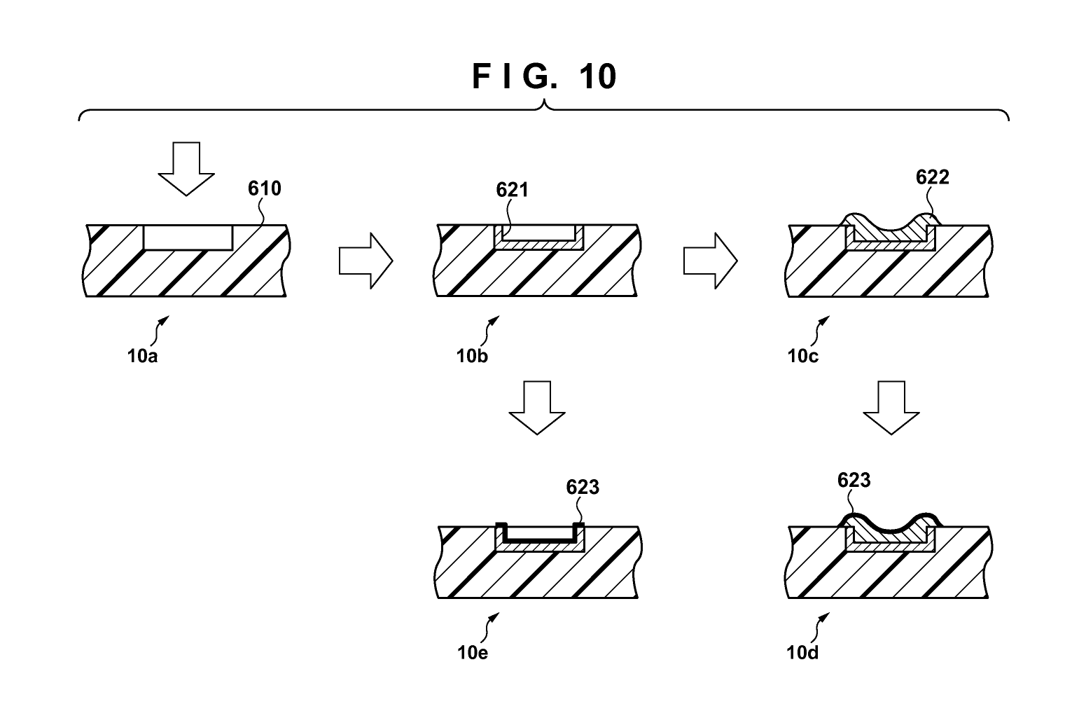

1. An electroless plating layer 621 is formed on a surface of a resin article 610. Specifically, as shown in a portion 10a of FIG. 10, the resin article 610 is modified to have a surface roughness Ra of 1.50 nm or more at an interface between the resin article 610 and the electroless plating layer 621. Thereafter, electroless plating is performed to produce a resin article with plating layer 600 having the electroless plating layer 621 at the modified portion as shown in a portion 10b of FIG. 10. The interface between the resin article 610 and the electroless plating layer 621 thus formed is visually recognized as having a black color. In other words, a plating layer 620 (one-layer configuration) including the electroless plating layer 621 exhibits a black color at an interface between the plating layer 620 and the resin article 610. In one embodiment, the surface of the resin article 610 on which the plating layer 620 is provided is formed from a material having optical transparency.

As shown in a portion 10c of FIG. 10, if electroplating is performed after the electroless plating in order to further improve the conductivity, a resin article with plating layer 600 in which an electroplating layer 622 is formed on the electroless plating layer 621 may be produced. A plating layer 620 (two-layer configuration) thus formed, including the electroless plating layer 621 and the electroplating layer 622, exhibits a black color at an interface between itself and the resin article 610.

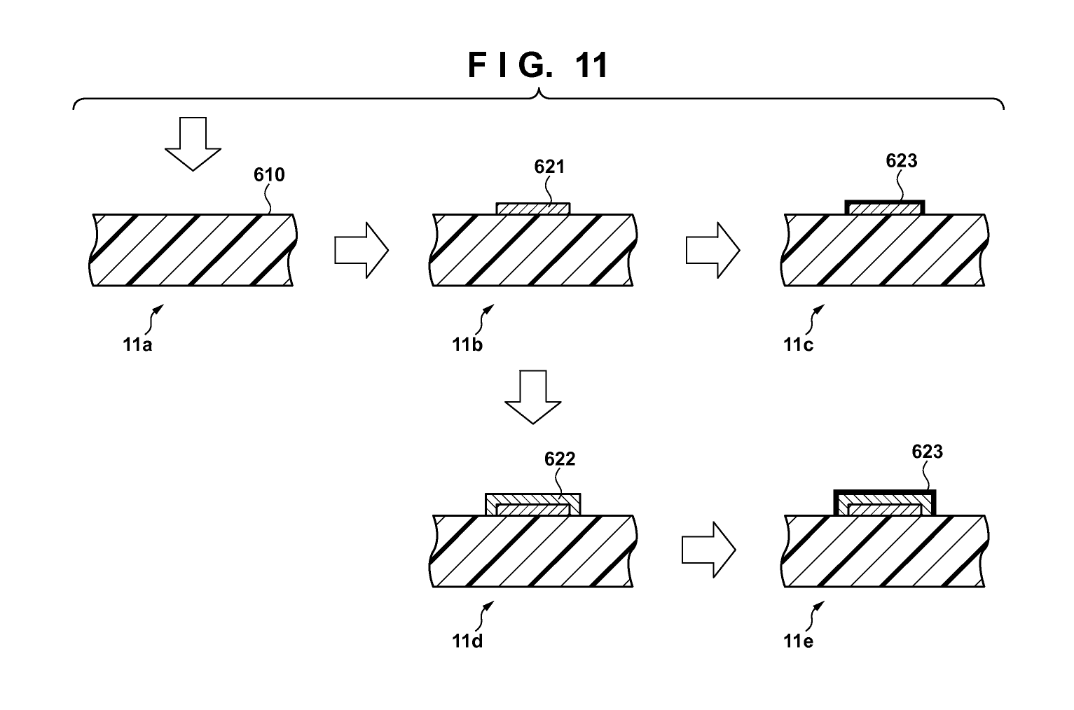

2. An electroless plating layer 621 is formed on a surface of a resin article 610. Specifically, as shown in a portion 11a of FIG. 11, the resin article 610 is modified to have a surface roughness Ra of less than 1.50 nm at an interface between the resin article 610 and the electroless plating layer 621. Thereafter, electroless plating is performed to form the electroless plating layer 621 at the modified portion as shown in a portion 11b of FIG. 11. Moreover, as shown in a portion 11c of FIG. 11, a black layer 623 is provided on the electroless plating layer 621 to produce a resin article with plating layer 600. The black layer may be formed by, for example, black plating as in the first embodiment. A plating layer 620 (two-layer configuration) thus formed, including the electroless plating layer 621 and the black layer 623, exhibits a black color at an opposite surface thereof from the resin article 610, i.e., an upper surface.

Also, as shown in a portion 11d of FIG. 11, in order to further improve the conductivity, electroplating may be performed after the electroless plating to form an electroplating layer 622 on the electroless plating layer 621. Thereafter, as shown in a portion 11e of FIG. 11, a black layer 623 may be additionally provided on the electroplating layer 622 to produce a resin article with plating layer 600. The black layer may be formed by, for example, black plating as in the first embodiment. A plating layer 620 (three-layer configuration) thus formed, including the electroless plating layer 621, the electroplating layer 622, and the black layer 623, exhibits a black color at an opposite surface thereof from the resin article 610.

Moreover, after the resin article 610 is modified to have a surface roughness Ra of less than 1.50 nm at the interface between the resin article 610 and the electroless plating layer 621, the electroless plating layer 621 may be formed by black electroless plating. A plating layer 620 (one-layer configuration) thus formed, including the electroless plating layer 621 formed by black electroless plating, exhibits a black color at an opposite surface thereof from the resin article 610.

3. An electroless plating layer 621 is formed on a surface of a resin article 610. Specifically, as shown in the portion 10a of FIG. 10, the resin article 610 is modified to have a surface roughness Ra of 1.50 nm or more at an interface between the resin article 610 and the electroless plating layer 621. Thereafter, electroless plating is performed to form the electroless plating layer 621 at the modified portion as shown in the portion 10b of FIG. 10. The interface between the resin article 610 and the electroless plating layer 621 thus formed is visually recognized as having a black color. Moreover, as shown in a portion 10e of FIG. 10, a black layer 623 may be additionally provided on the electroless plating layer 621 to form a resin article with plating layer 600. The black layer may be formed by, for example, black plating as in the first embodiment. A plating layer 620 (two-layer configuration) thus formed, including the electroless plating layer 621 and the black layer 623, exhibits a black color at the interface between itself and the resin article 610, and also exhibits a black color at an opposite surface thereof from the resin article 610. In one embodiment, the surface of the resin article 610 on which the plating layer 620 is provided is formed from a material having optical transparency.

Also, as shown in the portion 10c of FIG. 10, in order to further improve the conductivity, electroplating may be performed after the electroless plating to form an electroplating layer 622 on the electroless plating layer 621. Thereafter, as shown in a portion 10d of FIG. 10, a black layer 623 may be additionally provided on the electroplating layer 622 to produce a resin article with plating layer 600. The black layer may be formed by, for example, black plating as in the first embodiment. A plating layer 620 (three-layer configuration) thus formed, including the electroless plating layer 621, the electroplating layer 622, and the black layer 623, exhibits a black color at the interface between itself and the resin article 610, and also exhibits a black color at an opposite surface thereof from the resin article 610.

Moreover, after the resin article 610 is modified to have a surface roughness Ra of 1.50 nm or more at the interface between the resin article 610 and the electroless plating layer 621, the electroless plating layer 621 may be formed by black electroless plating. A plating layer 620 (one-layer configuration) thus formed, including the electroless plating layer 621 formed by black electroless plating, exhibits a black color at the interface between itself and the resin article 610, and also exhibits a black color at an opposite surface thereof from the resin article 610.

From the above various configurations, a suitable one may be selected, depending on required performance, such as electrical conductivity, cost, and adhesiveness.

In one embodiment, the process of causing the surface of the plating layer to have a black color (blackening process) may be performed after a pattern of plating layer in the shape of fine metal lines is formed on the transparent resin article as in the first embodiment. In this case, the plating layer exhibits a black color on an opposite surface thereof from the resin article. Such a layer exhibiting a black color may be formed by plating. As described above, in order to cause the surface of the plating layer to have a black color, the plating layer may be formed by black plating, or black plating is performed on the plating layer previously formed. In this case, the opposite surface of the plating layer from the resin article is formed by black plating. However, the process of performing black plating on a plating layer previously formed requires an additional step, likely leading to an increase in production cost or environmental cost. Also, the conductivity of the black plating layer is not high. In another embodiment described as follows, a plating layer having a low light reflectance can be formed without such a blackening process.

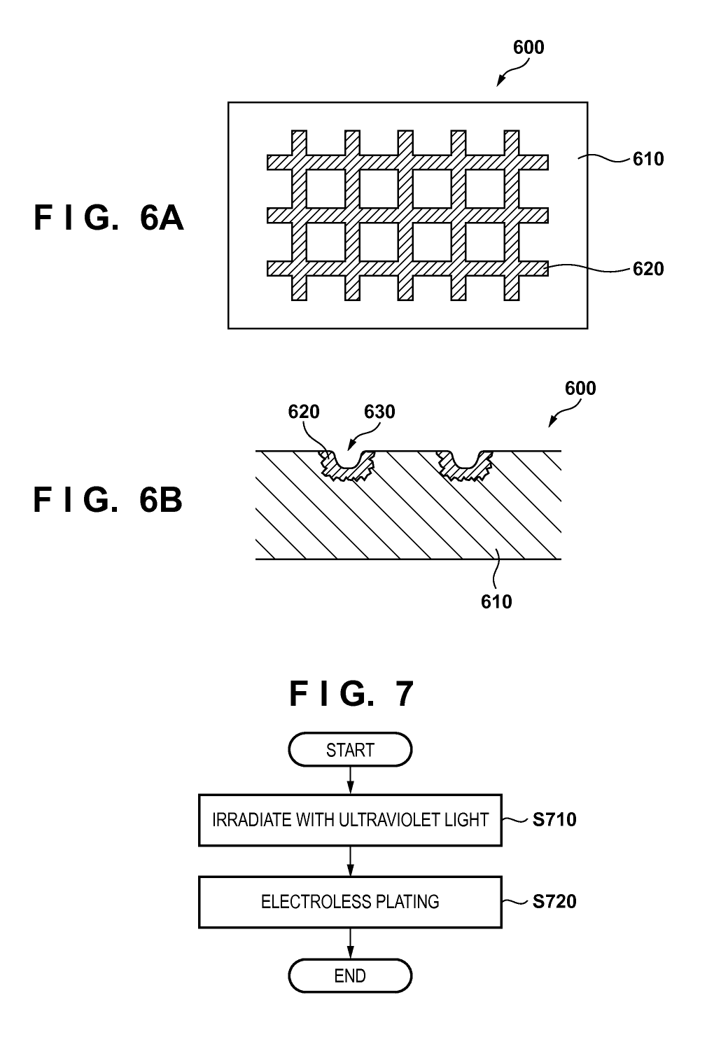

As shown in FIG. 6A, a resin article with plating layer 600 according to an embodiment of the present invention includes a resin article 610 and a pattern of plating layer 620 provided on a transparent portion of the resin article 610. An interface between the resin article 610 and the plating layer 620 exhibits a black color. Such a resin article with plating layer 600 does not need to be exactly completely transparent. For example, the resin article with plating layer 600 may be capable of passing a portion of incident light, depending on the application. In one embodiment, the fine metal line of the plating layer 620 has a width of 6 μm or less. In this case, it is difficult to visually recognize the fine metal line.

(Resin Article)

The resin article 610 is not particularly limited. Any resin article that has, at a surface, a resin material which allows for modification such that plating is selectively deposited on an ultraviolet light irradiated portion, may be employed. Examples of the resin material include cycloolefin polymers, polystyrene, polyethylene terephthalate, and the like. Other examples of the resin material include polyvinyl chloride, polycarbonate and polyimide. Resin materials similar to those described in the first embodiment may be employed.

In this embodiment, the plating layer 620 is provided on a transparent portion of the resin article 610. In other words, the resin article 610 has a transparent portion formed from a resin material having transparency (transparent resin material). Examples of the resin material having transparency include polyolefin resins such as cycloolefin polymers and polystyrene, polyester resins such as polyethylene terephthalate, vinyl resins such as polyvinyl chloride, and the like. Other examples of the resin material having transparency include polycarbonate and polyimide. In one embodiment, the resin material having transparency has a total luminous transmittance (JIS K7361-1: 1997) of 80% or more.

In this embodiment, the resin article 610 is assumed to be a film of a transparent resin material (transparent resin film). In this embodiment, the resin article with plating layer 600 including the plating layer 620 can be used as a transparent conductive film. As described above, the transparent conductive film does not need to have complete optical transparency. FIG. 6A shows the resin article with plating layer 600 which is a transparent conductive film. In FIG. 6A, the plating layer 620 is a metal conductor, and has a structure in which fine metal lines are arranged in a mesh pattern. However, the shape of the plating layer 620 is not particularly limited, and may have any arbitrary geometric pattern that can provide a desired light transmittance and conductivity. For example, the plating layer 620 may have a mesh pattern including a curve in order to prevent a moire pattern. The shape of the resin article 610 is not limited to a film, and may be any three-dimensional shape. For example, the resin article 610 may be in the shape of a substrate.

Not all the resin article 610 needs to be formed from a transparent resin material. For example, the resin article 610 may include a portion formed from a transparent resin material and a portion formed from a non-transparent resin material. Specifically, for example, the resin article 610 may have a multilayer structure including two or more layers. Alternatively the resin article 610 may be a composite material which has a coated structure in which a surface of another material is covered with a resin material. For example, a transparent inorganic layer may be provided on top of the resin article 610.

In this embodiment, the resin article 610 has a surface roughness Ra of 1.50 nm or more at the interface between the resin article 610 and the plating layer 620. As used herein, the surface roughness refers to an arithmetic average roughness Ra which is defined in JIS B0601: 2001. The surface roughness Ra may be calculated by measurement using an atomic force microscopy (AFM) and cross-sectional analysis. Owing to the resin article 610 having a surface roughness Ra of 1.50 nm or more, the plating layer 620 formed on the surface of the resin article 610 is visually recognized as having a black color when the bottom surface of the plating layer 620 is viewed through the resin article 610. Thus, if the resin article 610 has a surface roughness Ra of 1.50 nm or more, the plating layer 620 which exhibits a black color as viewed from the bottom surface can be formed without performing an additional process of causing the plating layer 620 to have a black color. As used herein, that the bottom surface of the plating layer 620 exhibits a black color means that light reflection at the interface between the resin article 610 and the plating layer 620 is reduced, and therefore, the interface is visually recognized as having a black color. In other words, in this embodiment, the plating layer 620 exhibits a black color as the plating layer 620 is viewed through a portion of the resin article 610 formed from a transparent resin. Therefore, when the resin article 610 is viewed from a side on which the plating layer 620 is not provided, a decrease in visibility through the resin article 610, that is caused by the gloss of the plating layer 620, can be reduced.

The blackness of the bottom surface of the plating layer 620 may be defined using the reflectance. In one embodiment, when the reflectance of the bottom surface of the plating layer 620 is measured through the resin article 610 with respect to a wavelength of 550 nm, the reflectance of the bottom surface of the plating layer 620 is 0.3 or less, 0.2 or less, or 0.1 or less. In one embodiment, when the reflectance of the plating layer 620 is measured through the resin article 610, the reflectance of the bottom surface of the plating layer 620 is 0.5 or less, 0.3 or less, or 0.2 or less, with respect to the wavelength range of 380-780 nm.

In one embodiment, in order to reduce the reflectance at the interface between the resin article 610 and the plating layer 620, the surface roughness Ra of the resin article 610 at the interface between the resin article 610 and the plating layer 620 is set to 1.80 nm or more or 2.00 nm or more. The surface roughness Ra of the resin article 610 at the interface between the resin article 610 and the plating layer 620 is set to 10.0 nm or less in one embodiment, 5.0 nm or less in another embodiment, 4.0 nm or less in a further embodiment, or 3.0 nm or less in a further embodiment. By setting the surface roughness Ra to be lower than a particular value, the reflectance can be further reduced in a long wavelength region in which the reflectance tends to be high.

In one embodiment, as shown in FIG. 6B, all or a portion of the plating layer 620 is buried in a recessed portion 630 formed on the resin article 610. The plating layer 620 of this embodiment is less likely to come off the resin article 610, compared to when the plating layer is formed on a flat and even resin surface. When the resin article with plating layer 600 is in the form of a thin film such as a transparent conductive film, the thickness of the resin article with plating layer 600 can be easily reduced because the plating layer 620 is buried in the resin article 610. The recessed portion 630 may be formed, for example, by irradiating a portion of the resin article 610 which is formed from a transparent resin material with an ultraviolet laser as described below.

An example configuration of the resin article with plating layer 600 which is a transparent conductive film will now be described. The shape of the resin article 610 which is a transparent resin film is not particularly limited, and may be suitably selected, depending on the application. The thickness of the resin article 610 is not particularly limited. In one embodiment, the thickness of the resin article 610 is 5.0 μm or more and 1.0 mm or less in order to provide sufficient strength and cause it to be easy to roll up.

When the resin article 610 which is a transparent resin film has the recessed portion 630, the shape and position of the recessed portion 630 may be suitably selected, depending on the shape of the plating layer 620 which is a conductor. In one embodiment, the recessed portion 630 has an elongated shape. The depth of the recessed portion 630 is not particularly limited, and may, for example, be 0.01 μm or more and 5.0 μm or less. The width of the recessed portion 630 is not particularly limited, and may, for example, be 2.0 μm or more and 100 μm or less.

The resin article 610 which is a transparent resin film may have a plurality of the recessed portions 630. For example, in one embodiment, the resin article 610 has a plurality of the recessed portions 630 which are in parallel with each other. Alternatively, the resin article 610 may have a first plurality of the recessed portions 630 which are in parallel with each other, and a second plurality of the recessed portion 630 which are in parallel with each other, where the first plurality of recessed portions and the second plurality of recessed portion intersect to form a mesh pattern. The mesh pattern may be suitably selected, depending on the application of the resin article with plating layer 600 which is a transparent conductive film. For example, an interval between adjacent ones of the recessed portions 630, that are in parallel with each other, is not particularly limited, and may, for example, be 50 μm or more and 1.0 mm or less. By increasing the interval, the light transmittance of the resin article with plating layer 600 is improved. By decreasing the interval, the resistance of the plating layer 620 which is a conductor can be easily sufficiently reduced. As described above, the mesh pattern is not limited to a lattice pattern, and may be various geometric patterns when necessary, or may be a curve pattern.

(Plating Layer)

A material for the plating layer 620 is not particularly limited. Any material that can conduct electricity may be employed. Any metal material may be employed. For example, when the plating layer 620 is formed by electroless plating, a material for the plating layer 620 may be, but is not limited to, copper, nickel, an alloy such as copper-nickel or the like, zinc oxide, or the like.

It is advantageous for the plating layer 620 to be formed from a material having a high conductivity, such as copper. For example, a transparent electrode including an ITO film has a sheet resistance of about 100 Ω/sq. The resistance can be reduced by increasing the thickness of the ITO film. However, in this case, the optical transparency decreases. Therefore, there is a practical upper limit on the thickness. On the other hand, in one embodiment, a transparent electrode having a copper mesh as the plating layer 620 has a sheet resistance of about 0.5 Ω/sq. Thus, in this embodiment, a significantly low resistance can be achieved, and it is advantageous to reduce a deterioration in a signal and provide a transparent electrode having a large area. In general, when a transparent electrode for a touch panel of 10 inches or more is produced, it is advantageous to employ a highly conductive material, such as copper.

An ITO film has low flexibility and is easily broken. Therefore, a transparent resin film having an ITO film formed on an entire surface thereof is not highly resistant to bending. On the other hand, the plating layer 620 may be formed from a material which is easily bent. For example, copper mesh has good conformability with respect to deformation, and therefore, a transparent electrode having a copper mesh as the plating layer 620 can be expected to have high flexibility and bendability. Thus, the resin article with plating layer 600 of this embodiment is expected to be applied as a transparent electrode to a wider range of applications.

The plating layer 620 may have a multilayer structure including a plurality of metal layers. For example, the plating layer 620 may be obtained by forming a first metal layer using a first technique such as electroless plating or the like and then forming a second metal layer using a second technique such as electroplating or the like. Examples of a material for the metal layer provided by electroplating include, but are not limited to, copper, nickel, copper-nickel alloy, zinc oxide, zinc, silver, cadmium, iron, cobalt, chromium, nickel-chromium alloy, tin, tin-lead alloy, tin-silver alloy, tin-bismuth alloy, tin-copper alloy, gold, platinum, rhodium, palladium, palladium-nickel alloy, and the like. Silver or the like may also be deposited on the plating layer 620 by displacement plating or the like.

The plating layer 620 may have any shape, and may be in the shape of, for example, a fine conductive line. The plating layer 620 is arranged on the resin article 610 according to a predetermined pattern. The predetermined pattern may be a mesh pattern or the like. In this case, the mesh pattern is not particularly limited. Alternatively, a pattern of a stripe, square, rectangle, rhombus, honeycomb, curve, or indefinite shape may be used.

In one embodiment in which the recessed portion 630 is formed in the resin article 610, all or a portion of the plating layer 620 is buried in the recessed portion 630. The plating layer 620 may cover substantially the entire surface of the recessed portion 630. In one embodiment, a width of the plating layer 620 corresponds to a width of the recessed portion 630, and is, for example, 2.0 μm or more and 100 μm or less. In one embodiment in which the plating layer 620 is arranged in a mesh pattern, an interval between adjacent conductive lines which are in parallel with each other, i.e., a width of a void, may be, but is not particularly limited to, 5.0 μm or more and 1.0 mm or less. In one embodiment, the percentage of a portion in which the plating layer 620 is not provided, in a portion in which the plating layer 620 is arranged in a mesh pattern, i.e., an aperture ratio, is 60% or more. Here, the width of the plating layer 620 refers to a width of the plating layer 620 along the surface of the resin article 610.

A thickness of the plating layer 620 is not particularly limited, and is 0.02 μm or more in one embodiment, 5.0 μm or more in another embodiment, 100 μm or less in one embodiment, or 20 μm or less in another embodiment. By decreasing the thickness, the line width of the pattern can be easily reduced. By increasing the thickness, sufficient electromagnetic wave shield capability or sufficiently low resistance can be provided. Here, the thickness of the plating layer 620 refers to a thickness of the plating layer 620 along a direction perpendicular to the surface of the resin article 610.

(Method for Manufacturing Conductive Film)

A method for manufacturing the resin article with plating layer 600 of this embodiment is not particularly limited, and may, for example, be a suitable combination of photolithography, vapor deposition, plating, and the like. An example method for manufacturing the resin article with plating layer 600 of this embodiment (hereinafter referred to as “the manufacturing method of this embodiment”) will be described. The manufacturing method of this embodiment has a modification step and a formation step. These steps will now be described in detail with reference to a flowchart shown in FIG. 7.

(Modification Step)

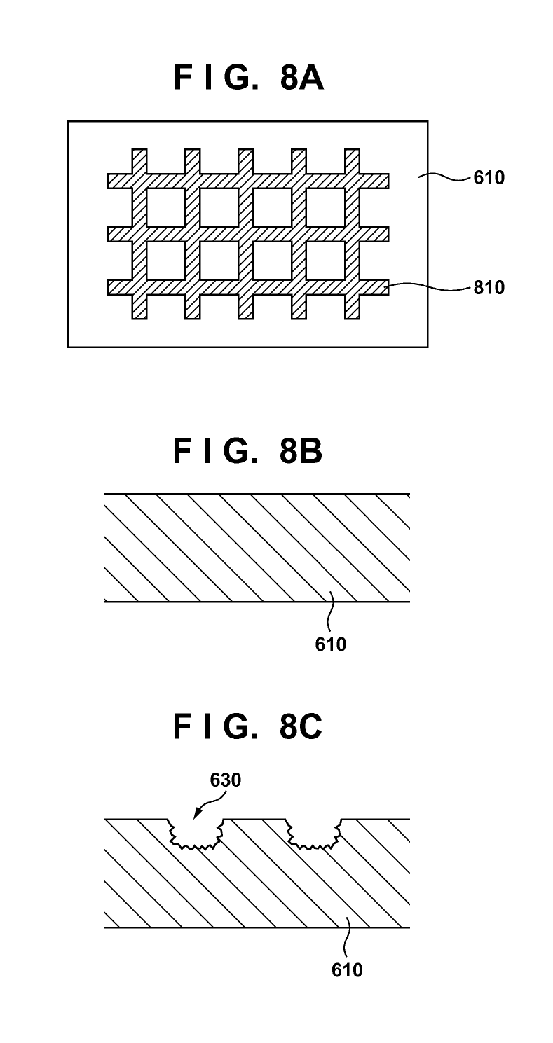

In a modification step (S710), a surface of the resin article 610, e.g., a portion of the transparent surface, i.e., a portion 810 in which the plating layer 620 is to be formed, is irradiated with an ultraviolet laser or ultraviolet lamp so that the portion is modified and is caused to have a rough surface. Thus, the modification step includes the step of causing a portion of the surface of the resin article 610 by ultraviolet light irradiation to have a rough surface. FIG. 8A is a top view of the resin article 610 which is a transparent resin film. FIG. 8B is a cross-sectional view of the resin article 610 of FIG. 8A. As shown in FIG. 8A, the portion 810 of the resin article 610 on which the plating layer 620 is to be formed is modified by ultraviolet light irradiation. In one embodiment, ultraviolet light having a wavelength of 243 nm or less is used for the irradiation. The ultraviolet light having a wavelength of 243 nm or less promotes the modification of the surface of the resin article 610.

In one embodiment, the irradiation of the resin article 610 with the ultraviolet light is performed in an atmosphere containing at least one of oxygen and ozone or in an atmosphere containing oxygen or ozone. Specifically, for example, the resin article 610 may be irradiated with the ultraviolet light in the atmosphere. In another embodiment, in order to promote the modification to a greater extent, the irradiation is performed in an atmosphere containing ozone. However, as described in the first embodiment, the resin article 610 may be irradiated with the ultraviolet light in an atmosphere containing other gases.

As described in the first embodiment, the ultraviolet light irradiation increases the chemical adsorption capability between the resin article 610 and the plating layer 620. An embrittled portion caused by the oxidation of the surface of the resin article 610 is washed off in a preprocess step for plating, so that a fine rough surface is formed on the resin surface. The rough surface causes an interface between the resin article 610 and the plating layer 620 to have a black color. Moreover, physical adsorption capability between the resin article 610 and the plating layer 620 is increased. Moreover, the modified portion can be caused to selectively adsorb a catalyst ion during electroless plating.

In order to improve the light transmittance and cause the plating layer 620 not to be visually recognized, the width of a fine metal line included in the plating layer 620 may be reduced, for example, to several micrometers in one embodiment. In order to form the plating layer 620 having such a fine pattern, it is desirable to use ultraviolet light having a wavelength 243 nm or less because a fine pattern is more easily formed using a shorter wavelength.

A first and a second method of modifying the resin article 610 using the ultraviolet light will now be described.

(1) First Method

According to one embodiment, in the modification step, the ultraviolet light irradiation is performed using an ultraviolet lamp, ultraviolet LED, or the like which continuously emits the ultraviolet light, to modify the resin article 610. For example, if a photomask, metal mask, or the like corresponding to the shape of the plating layer 620 is inserted into an optical system for the ultraviolet light, the portion 810 of the resin article 610 in which the plating layer 620 is to be formed can be selectively irradiated with the ultraviolet light.

Such ultraviolet light can be emitted using an ultraviolet lamp, ultraviolet LED, or the like which continuously emits the ultraviolet light. The energy density at a main wavelength of the ultraviolet light for the irradiation is not particularly limited, provided that the modification is achieved, and may, for example, be 1.0×10⁻³ W/cm² or more, or 1.0×10² W/cm² or less.

As the ultraviolet lamp, one similar to that which is described in the first embodiment may be used.

When the resin article 610 is irradiated with the ultraviolet light, the ultraviolet light irradiation is controlled to provide a desired irradiation amount. The irradiation amount can be controlled by changing the irradiation time. Alternatively, the irradiation amount can be controlled by changing the power, number, irradiation distance, or the like of ultraviolet lamps.

Conditions for the ultraviolet light irradiation are selected so that the interface between the resin article 610 and the plating layer 620 is caused to have a black color, and plating is deposited on the modified portion 810. In general, the more the irradiation amount of the ultraviolet light is, the more significant the surface roughness of the modified portion 810 becomes. The fine rough surface thus formed can decrease the reflectance of the interface between the resin article 610 and the plating layer 620. On the other hand, the more significant the surface roughness is, the more easily plating is deposited on the modified portion 810.

In one embodiment, in order to achieve both of the above characteristics, the irradiation is performed using the ultraviolet light in a cumulative irradiation amount of 400 mJ/cm² or more at a main wavelength thereof. In one embodiment, in order to decrease the reflectance of the interface between the resin article 610 and the plating layer 620 and the process time, the irradiation is performed using the ultraviolet light in a cumulative irradiation amount of 1000 mJ/cm² or less at a main wavelength thereof.

However, conditions for deposition of plating may vary depending on the type of the plating solution, the type of the resin article 610, the amount of contamination on the substrate of the resin article 610, the concentration, temperature, pH, and aging of the plating solution, the fluctuation of the power of the ultraviolet lamp, or the like. In this case, based on the above numerical values, the irradiation amount of the ultraviolet light may be suitably determined.

(2) Second Method

In another embodiment, the portion 810 of the surface of the resin article 610 in which the plating layer 620 is to be formed is modified using a combination of two or more different modification methods. Specifically, in one embodiment, the modification process is performed on a portion of the surface of the resin article 610 two or more times using different methods. The plating layer 620 can be deposited within only a desired area by using a combination of a first modification process capable of modifying only a desired area with high precision and a second modification process capable of achieving a greater amount of modification.

The second method described below has the following advantages. Specifically, in the first method, if the ultraviolet light irradiation is performed using an ultraviolet lamp, the ultraviolet lamp emits diffused light which does not have high ability to travel in a straight line, and therefore, it may be difficult to achieve position-selective irradiation. If the slit width of a photomask is decreased, diffraction may occur, so that the irradiated area may become wider, and therefore, the irradiation intensity of the ultraviolet light may decrease. Moreover, if the ultraviolet light irradiation is continued, both the photomask and the resin article 110 undergo thermal expansion. In this case, the irradiation position may be displaced due to a difference in thermal expansion coefficient between the photomask and the resin article 610. These problems are significant when the plating layer 620 which is not easily visually recognized is formed, e.g., when the plating layer 620 which has a fine pattern including fine metal lines having a width of several micrometers. According to the second method, it is easier to form the plating layer 620 having a fine pattern.

In one embodiment, the resin article 610 is modified by both the irradiation step of irradiating with ultraviolet light having a high energy density and the oxidation step of modifying the surface of the resin article 610 using the oxidation process. In this case, in the irradiation step, the portion 810 of the resin article 610 in which the plating layer 620 is to be formed is selectively irradiated with the ultraviolet light. Thereafter, in the oxidation step, the oxidation process is performed on a portion including the portion 810 in which the plating layer 620 is to be formed. By utilizing such a method, the portion 810 in which the plating layer 620 is to be formed is modified by the irradiation step with high precision, and the lack of modification in the irradiation step can be compensated by the oxidation step. In one embodiment, the oxidation process is performed on a portion which is larger than the portion 810 in which the plating layer 620 is to be formed, and therefore, encompasses the portion 810, or the entire resin article 610. In this case, the intensity of the oxidation process can be limited so that plating is not deposited outside the portion 810 in which the plating layer 620 is to be formed.

Specifically, the resin article 610 can be modified using the irradiation step and oxidation step described in the first embodiment. For example, the resin article 610 may be modified by performing the irradiation step of irradiating a portion of the surface of the resin article 610 with an ultraviolet laser of 243 nm or less, and after the irradiation step, the oxidation step of performing the oxidation process on a region including that portion of the surface of the resin article 610. In the oxidation step, the oxidation process may be performed by irradiating with ultraviolet light of 243 nm or less using, for example, an ultraviolet lamp or the like. These irradiation step and oxidation step may be performed in an atmosphere containing at least one of oxygen and ozone. As described in the first embodiment, if the resin article 610 is irradiated with the laser in the irradiation step, the recessed portion 630 is formed in the laser irradiated portion as shown in FIG. 8C.

When an ultraviolet laser is used for the irradiation in the irradiation step, and ultraviolet light is used for the irradiation in the oxidation step, the irradiation amount of the ultraviolet laser in the irradiation step, and the irradiation amount of the ultraviolet light in the oxidation step, are adjusted to cause the interface between the resin article 610 and the plating layer 620 to have a black color. An ultraviolet laser has the ablation effect. Therefore, an ultraviolet laser can be used to easily alter the surface of the resin article 610 into a rough surface so that the interface between the resin article 610 and the plating layer 620 is caused to have a black color. In one embodiment, as described in the first embodiment, an ultraviolet laser having a wavelength of 243 nm or less is used for the irradiation in the irradiation step, and ultraviolet light having a wavelength of 243 nm or less from an ultraviolet lamp or the like is used for the irradiation in the oxidation step. For example, in the irradiation step, an ultraviolet laser having an energy density per pulse of 50 mJ/cm² or more and 5000 mJ/cm² or less may be used for the irradiation. Such an ultraviolet laser may be provided using an ArF excimer laser. If the ultraviolet laser is used, then when the irradiation amount of ultraviolet light is small in the oxidation step, for example, when the irradiation time is short or the power of the ultraviolet lamp is weak, the interface between the resin article 610 and the plating layer 620 can be caused to have a black color.

The number of times the ultraviolet laser irradiation is performed is not particularly limited. In one embodiment, the ultraviolet laser irradiation is performed a plurality of times, e.g., 5 times or more or 10 times or more. By performing the ultraviolet laser irradiation a plurality of times, the reflectance of the interface between the resin article 610 and the plating layer 620 tends to decrease. In general, it is known that the higher the height of the surface unevenness of a film, and the higher the periodicity, the higher the antireflection effect of the film. It is considered that, by performing the ultraviolet laser irradiation a plurality of times, the randomness of the surface unevenness of the resin article 610 is reduced, i.e., the periodicity of the unevenness increases, and therefore, the reflectance decrease. The irradiation amount of the ultraviolet light in the irradiation step is not particularly limited, provided that plating is selectively deposited.

(Formation Step)

In the formation step (S720), a layer exhibiting a black color is formed by plating on a portion of the surface of the resin article 610. For example, in the formation step, electroless plating is performed on the resin article 610. As shown in FIG. 6B, by the formation step, the plating layer 620 having a bottom surface exhibiting a black color is selectively formed on the modified portion 810 of the surface of the resin article 610. According to this embodiment, it is not essential to perform patterning on the plating layer by a technique, such as etching or the like, after the plating layer is formed.

The specific electroless plating technique is not particularly limited. A technique similar to that which is described in the first embodiment may be employed. As in the first embodiment, after the electroless plating, electroplating may be additionally performed on the resin article 610. By using such a technique, the resin article with plating layer 600 can be easily manufactured.

The resin article with plating layer 600 obtained by the above method has the resin article 610, and the plating layer 620 provided on the surface of the resin article 610. The plating layer 620 exhibits a black color. The plating layer 620 exhibits a black color at the interface between itself and the resin article 610. In one embodiment in which the resin article with plating layer 600 is a transparent conductive film, the resin article 610 at the portion in which the plating layer 620 is provided is formed from a material having optical transparency. In particular, when the above second method is used, the resin article 610 has, in the surface thereof, the modified portion formed by the ultraviolet laser irradiation and the oxidation process following the ultraviolet laser irradiation. Also, the plating layer 620 provided by plating is provided on the modified portion irradiated with the ultraviolet laser.

### EXAMPLES

### XPS Measurement

In the description that follows, the amount of oxygen atoms introduced into the resin surface was measured by XPS analysis. The measured oxygen atom amount indicates the degree of progress in surface modification. As an XPS analysis device, Theta Probe, manufactured by Thermo Fisher Scientific Inc., was used. As an excited X-ray, a monochromatic X-ray where Al is the target (Al Kα 1486.6 eV) was used. In the measurement, an electron beam and an argon ion beam were used for irradiation in order to neutralize electric charge. Conditions for the analysis are shown in Table 1.

TABLE 1

| | Diameter of | | |
|---|---|---|---|
| | X-ray beam | Step energy | Pass energy |
| | (μm) | (eV) | (eV) |
| Qualitative | 300 | 1 | 200 |
| analysis | | | |
| Composition | 300 | 0.1 | 100 |
| analysis | | | |

[Modification Using Ultraviolet Lamp]

Table 2 shows a state of deposition of electroless plating, and a result of analysis of a state of surface modification by X-ray photoelectron spectroscopy (XPS) measurement, where a low-pressure mercury lamp was used as an ultraviolet light source, and the resin was irradiated with ultraviolet light. Specifically, a cycloolefin polymer material (ZEONOR film ZF-16, manufactured by ZEON CORPORATION, thickness: 100 μm, surface roughness: 1.01 nm) was irradiated with ultraviolet light from a low-pressure mercury lamp for a predetermined period of time, followed by XPS measurement. As the low-pressure mercury lamp, one similar to that which was used in Experiment 1 described below was used. The power of the low-pressure mercury lamp was 1.35 mW/cm² at a wavelength of 185 nm. Moreover, electroless plating was performed on the irradiated resin in a manner similar to a plating step performed in Experiment 1 described below.

In the “state of deposition of electroless plating” in Table 2, an open circle (o) indicates that plating was deposited, a cross (x) indicates that plating was not deposited, and an open triangle (Δ) indicates that plating was partially deposited. The “abundance ratio of oxygen atoms” indicates the ratio (atom %) of oxygen atoms to all atoms (excluding hydrogen atoms) measured by XPS measurement. The “oxygen atoms in C—O bonds %” indicates the ratio (atom %) of oxygen atoms included in C—O bonds to all atoms measured by XPS measurement. The “oxygen atoms in C═O bonds %” indicates the ratio (atom %) of oxygen atoms included in C═O bonds to all atoms measured by XPS measurement. In this case, “the abundance ratio of oxygen atoms”=“oxygen atoms in C—O bonds %”+“oxygen atoms in C═O bonds %.”

TABLE 2

| | Irradiation time of low-pressure ercury lamp | | | | | |
|---|---|---|---|---|---|---|
| | 0 min | 1 min | 2 min | 3 min | 4 min | 12 min |
| Cumulative | 0 mJ/cm² | 81 mJ/cm² | 162 mJ/cm² | 243 mJ/cm² | 324 mJ/cm² | 972 mJ/cm² |
| irradiation | | | | | | |
| amount (185 nm, | | | | | | |
| 1.35 mW/cm²) | | | | | | |
| State of | x | x | x | x | x | ∘ |
| plating | | | | | | |
| deposition | | | | | | |
| Abundance | 0.0 | 12.6 | — | — | 13.6 | 23.2 |
| ratio of | | | | | | |
| oxygen | | | | | | |
| atoms % | | | | | | |
| Oxygen | 0.0 | 8.2 | — | — | 7.8 | 10.0 |
| atoms in C—O | | | | | | |
| bonds % | | | | | | |
| Oxygen | 0.0 | 4.4 | — | — | 5.8 | 13.2 |
| atoms in | | | | | | |
| C═O bonds % | | | | | | |

As can be seen from Table 2, when the cumulative irradiation amount is 324 mJ/cm² or less, electroless plating is not deposited, and when the cumulative irradiation amount is 972 mJ/cm² or more, electroless plating is deposited. The result of the XPS measurement shows that when the abundance ratio of oxygen atoms of the resin surface is 13.6% or less, electroless plating is not deposited, and when 23.2% or more, electroless plating is deposited. It also shows that the irradiation time required is about 10 min.

[Modification by Laser]

Table 3 shows a state of deposition of electroless plating, and a result of analysis of a state of surface modification by XPS measurement, when the resin is irradiated with an ArF excimer laser. Specifically, a cycloolefin polymer material (ZEONOR film ZF-16, manufactured by ZEON CORPORATION, thickness: 100 μm, surface roughness: 1.01 nm) was irradiated with a predetermined number of pulses of an ArF excimer laser (main wavelength: 193 nm), followed by XPS measurement. The energy density per pulse in this case was 1000 mJ/cm². As the ArF excimer laser, one similar to that which was used in Experiment 1 described below was used. The items of Table 3 are similar to those of Table 2. Moreover, electroless plating was performed on the irradiated resin in a manner similar to a plating step performed in Experiment 1 described below.

TABLE 3

Number of pulses

| | 0 | 2 | 10 | 20 |
|---|---|---|---|---|
| State of plating | x | x | x | x |
| deposition | | | | |
| Abundance ratio of | 0 | 3.8 | — | 4.1 |
| oxygen atoms % | | | | |
| Oxygen atoms in C—O | 0 | 2.6 | — | 2.5 |
| bonds % | | | | |
| Oxygen atoms in C═O | 0 | 1.2 | — | 1.6 |
| bonds % | | | | |

As can be seen from Table 3, even when the number of pulses is changed, the abundance ratio of oxygen atoms is almost constant, i.e., around 4%, and therefore, the number of pulses is not proportional to the amount of surface modification. There was none of the conditions under which electroless plating was deposited. This may be because the surface modified by the laser was ablated, i.e., the modified portion was removed.

Table 4 shows a state of deposition of electroless plating, and a result of analysis of a state of surface modification by XPS measurement, when the energy density of an ArF excimer laser per pulse was 100 mJ/cm². The other conditions were the same as those of Table 3.

TABLE 4

Number of pulses

| | 0 | 20 | 100 | 200 |
|---|---|---|---|---|
| State of plating | x | x | x | x |
| deposition | | | | |
| Abundance ratio of | 0 | 7.3 | — | 8.7 |
| oxygen atoms % | | | | |
| Oxygen atoms in C—O | 0 | 4.5 | — | 5.8 |
| bonds % | | | | |
| Oxygen atoms in C═O | 0 | 2.8 | — | 2.9 |
| bonds % | | | | |

As can be seen from Table 4, even when the number of pulses is changed, the abundance ratio of oxygen atoms is almost constant, i.e., around 8%, and therefore, the number of pulses is not proportional to the amount of surface modification. There was none of the conditions under which electroless plating was deposited. However, compared to when the energy density per pulse was 1000 mJ/cm², the abundance of oxygen increased when the cumulative irradiation amount was the same. This may be because if the energy density of the laser is weak, the modified surface is not easily removed by ablation.

[Formation of Recessed Portion by Laser Irradiation]

A cycloolefin polymer material (ZEONOR film ZF-16, manufactured by ZEON CORPORATION, thickness: 100 μm, surface roughness: 1.01 nm) was irradiated with an ArF excimer laser (main wavelength: 193 nm). The energy density per pulse in this case was 100 mJ/cm² or 1000 mJ/cm². As the ArF excimer laser, one similar to that which was used in Experiment 1 described below was used. Thereafter, a depth of a recessed portion formed in a portion irradiated with the laser was measured using a contact stylus profilometer (Alpha-Step, manufactured by KLA-Tencor Corporation). The measurement was conducted around the center portion (second measurement) and two peripheral portions (first and third measurements) of the incident range of the laser. The measurement result is shown in Table 5.

TABLE 5

| Number | Cumulative | | | |
|---|---|---|---|---|
| of | irradiation | First | Second | Third |
| pulses | amount | measurement | measurement | measurement |
| Energy density per | | | | |
| pulse: 100 mJ/cm² | | | | |
| 20 pulses | 2000 mJ/cm² | Not measureable (no trace of | | |
| | | irradiation was observed) | | |
| 100 pulses | 10000 mJ/cm² | 1517 Å | 3547 Å | 1723 Å |
| 200 pulses | 20000 mJ/cm² | 1427 Å | 1708 Å | 2859 Å |
| Energy density per | | | | |
| pulse: 1000 mJ/cm² | | | | |
| 2 pulses | 2000 mJ/cm² | 1801 Å | 3009 Å | 1754 Å |
| 10 pulses | 10000 mJ/cm² | 11221 Å | 11604 Å | 9411 Å |
| 20 pulses | 20000 mJ/cm² | 24802 Å | 20615 Å | 22704 Å |

As can be seen from Table 5, as the energy density of the laser increases, a deeper recessed portion is formed. When the energy density of the laser was 1000 mJ/cm², the cumulative irradiation amount and the depth were almost proportional to each other. When the energy density of the laser was 100 mJ/cm², the depth was not substantially changed even when the cumulative irradiation amount was increased. This may be because when the material surface is modified, the physical properties of the material are changed, so that the ablation efficiency decreases, particularly when the energy density is low.

Thus, it was confirmed that a recessed portion is formed in a resin surface by laser irradiation. Also, it was found that the depth of the recessed portion can be controlled by controlling the energy density and irradiation amount of the laser.

### Experiment 1

### Substrate Process

In Experiment 1, as a substrate for electroless plating, a cycloolefin polymer material (ZEONOR film ZF-16, manufactured by ZEON CORPORATION, thickness: 100 μm, surface roughness: 1.01 nm), which is a resin material, was employed.

Initially, the following processes were performed before surface modification, in order to wash the substrate surface.
1. Ultrasonic washing with pure water at 50° C. for 3 min
2. Immersion in an alkaline washing solution (containing 3.7% sodium hydroxide) at 50° C. for 3 min
3. Ultrasonic washing with pure water at 50° C. for 3 min
4. Drying

(Irradiation Step)

Next, an irradiation step of irradiating a desired portion of the substrate with an ultraviolet laser was performed. The details of the ultraviolet laser used in Experiment 1 are the following.
Ultraviolet laser: ArF excimer laser (main wavelength 193 nm)
Ultraviolet laser source: LPXpro 305, manufactured by Coherent, Inc.
Irradiation conditions: frequency 50 Hz, pulse width 25 ns, 200 pulses
Energy density per pulse on irradiated surface: 100 mJ/cm²

For the substrate thus irradiated with the ultraviolet laser, the abundance ratio of oxygen atoms was measured by XPS measurement, and the result was 8.8%. Here, the measuring device XPS is not capable of measuring hydrogen atoms. Therefore, the abundance ratio of atoms in the surface of the cycloolefin polymer material in Experiment 1 was calculated only based on carbon atoms and oxygen atoms.

Also, after the cycloolefin polymer material was irradiated with 200 pulses of the ArF excimer laser, the shape of the substrate surface was checked using a scanning electron microscope (SEM). As a result, a recessed portion was formed in a laser irradiated portion, and the depth of the recessed portion was about 0.2 μm. The depth was able to be adjusted by increasing or decreasing the number of laser pulses.

(Oxidation Step)

Next, an oxidation step of performing irradiation using an ultraviolet lamp is performed on a desired portion of the substrate after the laser irradiation. The details of the ultraviolet lamp (low-pressure mercury lamp) used in Experiment 1 are as follows.
Low-pressure mercury lamp: UV-300, manufactured by SAMCO Inc. (main wavelength 185 nm, 254 nm)
Illuminance at an irradiation distance of 3.5 cm:
5.40 mW/cm² (254 nm)
1.35 mW/cm² (185 nm)

Specifically, the substrate of the cycloolefin polymer material which had been irradiated with 200 pulses of the ArF excimer laser, was further irradiated with ultraviolet light of 1.35 mW/cm² (185 nm) for one minute using the ultraviolet lamp located at a distance of 3.5 cm from the substrate. In this case, the cumulative exposure amount was 1.35 mW/cm²60 sec=81 mJ/cm².

The state of surface modification of the substrate thus irradiated with the ultraviolet light was analyzed by XPS measurement. The abundance ratio of oxygen atoms in a portion of the substrate which had been irradiated with the laser, after the irradiation with the ultraviolet lamp, was 20.1%. The abundance ratio of oxygen atoms in a portion of the substrate which had not been irradiated with the laser, after the irradiation with the ultraviolet lamp, was 12.6%. Thus, in Experiment 1, the abundance ratio of oxygen atoms in the portion of the substrate which had not been irradiated with the laser was reduced to 15% or less. Therefore, as described below, plating was able to be selectively deposited on the portion which had been irradiated with the laser.

(Plating Step)

Next, a plating step of performing electroless plating is performed on the substrate which had been irradiated with the ultraviolet light in the oxidation step. As an electroless plating solution, a Cu—Ni plating solution set “AISL,” manufactured by JCU CORPORATION, was used. Specific processes in the plating step are shown in Table 6.

TABLE 6

| | Process | |
|---|---|---|
| Steps | conditions | Remarks |
| Alkali treatment | 50° C., 2 min | Improvement in |
| | | degreasing and |
| | | wettability |
| Washing + drying | | |
| (air blow) | | |
| Conditioner step | 50° C., 2 min | Addition of catalyst ion |
| | | and substrate binder |
| Washing with warm | | |
| water + Washing + | | |
| drying (air blow) | | |
| Activator | 50° C., 2 min | Addition of catalyst ion |
| Washing + drying | | |
| (air blow) | | |
| Accelerator | 40° C., 2 min | Reduction and |
| | | metallization of |
| | | catalyst ion |
| Washing + drying | | |
| (air blow) | | |
| Electroless Cu—Ni | 60° C., 5 min | Deposition of |
| plating | | electroless plating |
| Washing + drying | | |
| (air blow) | | |

When electroless plating was performed according to the steps of Table 6, a plating layer was formed by electroless plating only at a portion which had been irradiated with the laser.

### Experiment 2

An irradiation step, oxidation step, and plating step which are similar to those of Experiment 1, except that the number of times the laser irradiation is performed in the irradiation step was changed, were performed, and it was determined by observation whether or not a plating layer was formed at a portion which had been irradiated with the laser. The result is shown in Table 7. In Table 7, an open circle (o) indicates that plating was deposited, and a cross (x) indicates that plating was not deposited.

TABLE 7

| | Cumulative irradiation |
|---|---|
| Abundance ratio of oxygen | amount in oxidation step |
| atoms after laser | 81 mJ/cm² (one-minute |
| irradiation | irradiation) |
| 0.0% | x |
| 3.8% | x |
| 4.2% | x |
| 7.1% | ∘ |
| 8.8% | ∘ |

As can be seen from Table 7, when ultraviolet light of 81 mJ/cm² is used for the irradiation in the oxidation step, then if the abundance ratio of oxygen atoms in the laser irradiated portion in the irradiation step is 6.5% or more, plating is deposited on the laser irradiated portion. Specifically, in Experiment 2 in which an ArF excimer laser having an energy density of 100 mJ/cm² was used for the irradiation, when the number of pulses was 20 or more, the abundance ratio of oxygen atoms was 6.5% or more. It is considered that even when the number of pulses is increased, the abundance ratio of oxygen atoms does not decrease, and therefore, there is not particularly an upper limit of the number of pulses. It was found that when the number of pulses is 200 or less, the abundance ratio of oxygen atoms is 6.5% or more.

### Experiment 3

An irradiation step, oxidation step, and plating step which are similar to those of Experiment 1, except that the number of times the laser irradiation is performed in the irradiation step was changed, and the ultraviolet laser irradiation was performed for 3 min in the oxidation step, were performed, and it was determined by observation whether or not a plating layer was formed at a portion which had been irradiated with the laser. The result is shown in Table 8. In Table 8, an open circle (o) indicates that plating was deposited, and a cross (x) indicates that plating was not deposited.

TABLE 8

| | Cumulative irradiation |
|---|---|
| Abundance ratio of oxygen | amount in oxidation step |
| atoms after laser | 243 mJ/cm² (three-minute |
| irradiation | irradiation) |
| 0.0% | x |
| 3.8% | ∘ |
| 4.2% | ∘ |
| 7.1% | ∘ |
| 8.8% | ∘ |

As can be seen from Table 8, when ultraviolet light of 243 mJ/cm² is used for the irradiation in the oxidation step, then if the abundance ratio of oxygen atoms in the laser irradiated portion of the irradiation step is 3.0% or more, plating is deposited on the laser irradiated portion.

### Example 1

As the resin article 610, a transparent insulating resin sheet of a cycloolefin polymer material (ZEONOR film ZF-16, manufactured by ZEON CORPORATION, thickness: 100 μm), was employed.

Initially, the portion 810 of the resin article 610 in which the plating layer 620 was to be formed was irradiated with ultraviolet light through a photomask in the atmosphere. Conditions for the ultraviolet light irradiation are the following.

Low-pressure mercury lamp: UV-300, manufactured by SAMCO Inc. (main wavelength 185 nm, 254 nm) Irradiation distance: 3.5 cm
Illuminance at an irradiation distance of 3.5 cm:
5.40 mW/cm² (254 nm)
1.35 mW/cm² (185 nm)
Irradiation time: 10 min

In this case, the cumulative exposure amount was 1.35 mW/cm²×600 sec=810 mJ/cm².

Next, an alkali treatment was performed on the resin article 610 which had been irradiated with the ultraviolet light. Specifically, the resin article 610 was immersed in an alkali treatment solution used in a Cu—Ni plating solution set “AISL,” manufactured by JCU CORPORATION, which was heated to 50° C., for 2 min. Thereafter, the resin article 610 was washed by stirring in pure water at 50° C. for 1 min.

Next, a binder addition treatment was performed on the resin article 610 after the alkali treatment. Specifically, the resin article 610 was immersed in a conditioner solution used in a Cu—Ni plating solution set “AISL,” manufactured by JCU CORPORATION, which was heated to 50° C., for 2 min. Thereafter, the resin article 610 was washed by stirring in pure water at 50° C. for 5 min.

Next, a catalyst ion addition treatment was performed on the resin article 610 after the conditioner treatment. Specifically, the resin article 610 was immersed in an activator solution used in a Cu—Ni plating solution set “AISL,” manufactured by JCU CORPORATION, which was heated to 50° C., for 2 min. Thereafter, the resin article 610 was washed by stirring in pure water at 50° C. for 1 min.

Next, a reduction treatment was performed on the resin article 610 after the catalyst ion addition treatment. Specifically, the resin article 610 was immersed in an accelerator solution used in a Cu—Ni plating solution set “AISL,” manufactured by JCU CORPORATION, which was heated to 50° C., for 2 min. Thereafter, the resin article 610 was washed by stirring in pure water at 50° C. for 1 min.

Next, electroless Cu—Ni plating was performed on the resin article 610 after the reduction treatment. Specifically, the resin article 610 was immersed in an electroless Cu—Ni solution used in a Cu—Ni plating solution set “AISL,” manufactured by JCU CORPORATION, which was heated to 60° C., for 5 min. Thereafter, the resin article 610 was washed by stirring in pure water at 50° C. for 1 min. By this treatment, the plating layer 620 which is a copper-nickel plating layer was formed on the portion 310 of the resin article 610 which had been irradiated with the ultraviolet light. Thus, the resin article with plating layer 600 was obtained. As the resin article with plating layer 600 thus obtained was viewed from a side on which the plating layer 620 was not formed, the plating layer 620 exhibited a black color. However, there was a mismatch observed between the shape of the plating layer 620 obtained and the shape of a photomask which was used during the ultraviolet light irradiation. This may be because light emitted from the ultraviolet lamp was diffused light, and the photomask and the resin article expanded to different sizes due to heat caused by the irradiation performed over as long as 10 min.

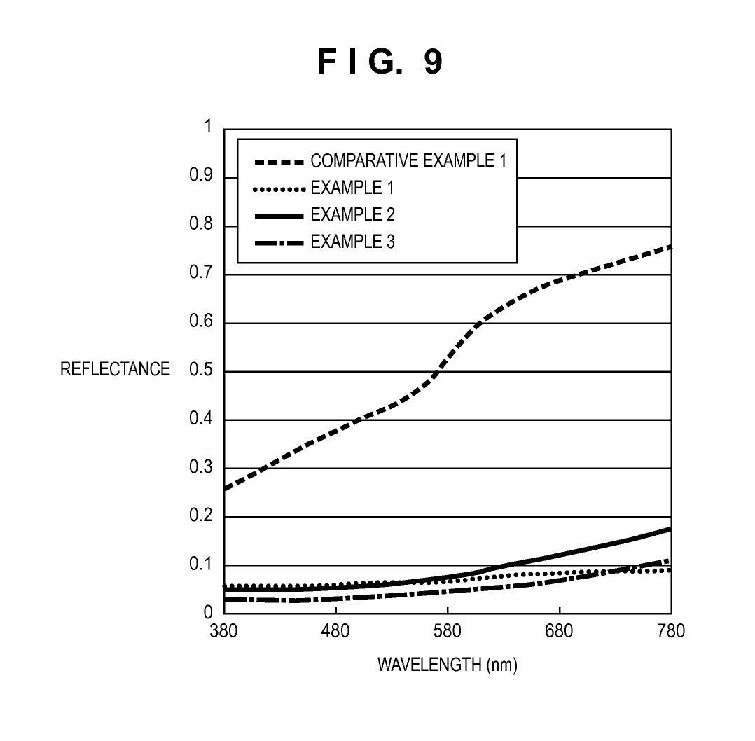

For the resin article with plating layer 600 thus obtained, the reflectance of the plating layer 620 through the resin article 610 was measured from a side on which the plating layer 620 was not formed, using a microspectroscopic system (DF-1037, manufactured by Techno-Synergy, Inc.). The measurement result is shown in FIG. 9.

The surface roughness of the resin article 610 was measured after each step as follows. In the measurement, employed was an atomic force microscopy (AFM) (NanoScopeV/Dimension Icon, manufactured by Bruker Corporation, measurement mode: tapping mode, measurement area: 10 μm×10 μm, number of measurement points: 512×512, scan speed: 1.0 Hz). Cross-sectional analysis was performed using the obtained measurement data to calculate the surface roughness Ra. The surface roughness Ra of the portion 810 of the resin article 610 which was irradiated with the ultraviolet light is the following.
Before ultraviolet light irradiation: Ra=0.47 nm
After ultraviolet light irradiation: Ra=0.26 nm
After alkali treatment and washing: Ra=0.87 nm
After conditioner treatment and washing: Ra=2.42 nm

As described above, the surface roughness Ra of the resin article 610 before the modification was 0.47 nm. By the ultraviolet light irradiation, the flatness of the resin article 610 was improved, resulting in the surface roughness Ra of 0.26 nm. This may be because projections of the surface of the resin article 610 were oxidized and decomposed due to the modification. Thereafter, the surface roughness Ra increased due to the alkali treatment, and still increased due to the conditioner treatment. This may be because the surface of the resin article 610 was embrittled by the ultraviolet light irradiation, and the embrittled portion was washed and removed by the alkaline solution, and the conditioner solution containing a surfactant. In the subsequent catalyst ion addition treatment and reduction treatment, the surface roughness Ra of the modified portion remained almost unchanged. The surface roughness of a portion of the resin article 610 which had not been irradiated with the ultraviolet light remained unchanged against the treatments. As a result, it was considered that the surface roughness of the resin article 610 at an interface between itself and the plating layer 620 can be reliably evaluated using the surface roughness of the resin article 610 after the conditioner treatment.

### Example 2

The resin article with plating layer 600 was produced in a manner which is similar to that of Example 1, except that conditions for ultraviolet light irradiation were changed. In Example 1, the portion 810 of the resin article 610 in which the plating layer 620 was to be formed was irradiated with an ultraviolet laser through a mask in the atmosphere, and thereafter, the entire surface of the resin article 610 was irradiated with ultraviolet light from an ultraviolet lamp in the atmosphere.

Conditions for the ultraviolet laser irradiation are the following.
Ultraviolet laser: ArF excimer laser (main wavelength 193 nm)
Ultraviolet laser source: LPXpro 305, manufactured by Coherent, Inc.
Irradiation conditions: pulse width 25 ns, 1 pulse
Energy density per pulse on irradiated surface: 1000 mJ/cm²

Conditions for the ultraviolet light irradiation using the low-pressure mercury lamp are the following.
Low-pressure mercury lamp: UV-300, manufactured by SAMCO Inc. (main wavelength 185 nm, 254 nm)
Irradiation distance: 3.5 cm
Illuminance at an irradiation distance of 3.5 cm:
5.40 mW/cm² (254 nm)
1.35 mW/cm² (185 nm)
Irradiation time: 3 min and 30 sec

In this case, the cumulative exposure amount was 1.35 mW/cm²×210 sec=about 284 mJ/cm². The surface of the portion 810 after the conditioner treatment in which the plating layer 620 was to be formed was measured using an atomic force microscopy (AFM) (scanning probe microscope JSPM-4210, manufactured by JEOL Ltd.), to find that the surface roughness Ra was 4.47 nm.

As the resin article with plating layer 600 thus obtained was viewed from a side on which the plating layer 620 was not formed, the plating layer 620 exhibited a black color. For the resin article with plating layer 600 thus obtained, the reflectance of the plating layer 620 through the resin article 610 was measured from a side on which the plating layer 620 was not formed, using a microspectroscopic system (DF-1037, manufactured by Techno-Synergy, Inc.). The measurement result is shown in FIG. 9.

### Example 3

The resin article with plating layer 600 was produced in a manner which is similar to that of Example 2, except that conditions for ultraviolet laser irradiation were changed. Conditions for ultraviolet laser irradiation in Example 3 are the following.
Ultraviolet laser: ArF excimer laser (main wavelength 193 nm)
Ultraviolet laser source: LPXpro 305, manufactured by Coherent, Inc.
Irradiation conditions: frequency 50 Hz, pulse width 25 ns, 10 pulses
Energy density per pulse on irradiated surface: 2000 mJ/cm²

The surface of the portion 810 after the conditioner treatment in which the plating layer 620 was to be formed was measured using an atomic force microscopy (AFM) (scanning probe microscope JSPM-4210, manufactured by JEOL Ltd.), to find that the surface roughness Ra was 2.28 nm.

As the resin article with plating layer 600 thus obtained was viewed from a side on which the plating layer 620 was not formed, the plating layer 620 exhibited a black color. For the resin article with plating layer 600 thus obtained, the reflectance of the plating layer 620 through the resin article 610 was measured from a side on which the plating layer 620 was not formed, using a microspectroscopic system (DF-1037, manufactured by Techno-Synergy, Inc.). The measurement result is shown in FIG. 9.

### Example 4

As the resin article 110, an insulating resin sheet of a cycloolefin polymer material (ZEONOR film ZF-16, manufactured by ZEON CORPORATION, thickness: 100 μm, surface roughness: 1.01 nm), was employed.

Initially, each portion of the resin article 110 in which the conductor 520 was to be formed was irradiated with a plurality of pulses of an ArF excimer laser (wavelength: 193 nm). Specifically, the resin article 110 was scanned with the laser according to a mesh pattern having a mesh width of 20 μm and a mesh interval of 300 μm. FIG. 3A shows the portion 310 of the resin article 110 which has been irradiated with the laser. Conditions for the laser irradiation are the following.
Ultraviolet laser source: LPXpro 305, manufactured by Coherent, Inc.
Irradiation conditions: frequency 50 Hz, pulse width 25 ns
Energy density per pulse on irradiated surface: 2000 mJ/cm²
Total amount of irradiation energy: 10 pulses, a total of 20000 mJ/cm²

The recessed portion 140 was formed in the portion which had been irradiated with the ultraviolet laser. The depth of the recessed portion 140 was measured using a contact stylus profilometer, to find that the depth was about 2 μm.

Next, the entire surface of the resin article 110 was irradiated with ultraviolet light using a low-pressure mercury lamp, to oxidize a region of the resin article 110 including the recessed portion 140. Conditions for the ultraviolet light irradiation are the following.
Low-pressure mercury lamp: UV-300, manufactured by SAMCO Inc. (main wavelength 185 nm, 254 nm)
Irradiation distance: 3.5 cm
Illuminance immediately below the lamp: 5.40 mW/cm² (254 nm)
Irradiation time: 3 min and 30 sec

Next, an alkali treatment was performed on the resin article 110 which had been irradiated with the ultraviolet light. Specifically, the resin article 110 was immersed in an alkali treatment solution used in a Cu—Ni plating solution set “AISL” shown in Table 6, manufactured by JCU CORPORATION, which was heated to 50° C., for 2 min.

Next, a catalyst ion was added to the resin article 110 after the alkali treatment. Specifically, the resin article 110 was immersed in an activator solution containing palladium (II)-basic amino acid complex (brand name: ELFSEED ES-300, manufactured by JCU CORPORATION), which was heated to 50° C., for 2 min (activator treatment). Moreover, an activation treatment which reduces the catalyst ion was performed on the resin article 110 to which the catalyst ion had been added. Specifically, the resin article 110 was immersed in an accelerator solution (brand name: ELFSEED ES-400, manufactured by JCU CORPORATION), which was heated to 35° C., for 2 min (accelerator treatment).

Next, electroless plating was performed on the resin article 110 after the catalyst activation treatment. Specifically, the resin article 110 was immersed in a specialized electroless Cu—Ni plating solution used in a Cu—Ni plating solution set “AISL” shown in Table 6, manufactured by JCU CORPORATION, which was heated to 60° C., for 5 min. The thickness of the electroless Cu—Ni plating layer was 0.4 μm.

Next, copper electroplating was performed on the resin article 110 after the electroless plating. Specifically, a copper plating layer was formed on the electroless plating layer using a plating solution set (CU-BRITE RF) manufactured by JCU CORPORATION. The thickness of the copper plating layer was 4 μm.

Finally, electroless black plating was performed on the copper plating layer. Specifically, the resin article 110 was immersed in an electroless black nickel plating solution (brand name: KANIBLACK, manufactured by Japan Kanigen Co., Ltd.), which was heated to 90° C., for 10 min. The thickness of the electroless black plating layer was 2 μm. Thus, the transparent conductive film 100 was produced.

The transparent conductive film thus obtained was observed. As shown in FIG. 3B, the conductor 520 was formed with high precision according to a mesh pattern 320 having a mesh width of about 20 μm and a mesh interval of 300 μm. In this case, the conductor 520 exhibited a black color as the conductive film 100 was viewed from a side on which the conductor 520 was not formed. The conductor 520 also exhibited a black color as viewed from a side on which the conductor 520 was formed. Thus, the conductor 520 exhibited a black color on the opposite sides thereof.

### Comparative Example 1

The resin article with plating layer 600 was produced in a manner which is similar to that of Example 1, except that conditions for ultraviolet light irradiation were changed. Conditions for ultraviolet light irradiation in Comparative Example 1 are the following.
Low-pressure mercury lamp: UV-300, manufactured by SAMCO Inc. (main wavelength 185 nm, 254 nm)
Irradiation distance: 1.0 cm
Illuminance at an irradiation distance of 1.0 cm:
   Highest illumination point:
   7.30 mW/cm² (254 nm)
   1.83 mW/cm² (185 nm)
   Lowest illumination point:
   0.64 mW/cm² (254 nm)
   0.16 mW/cm² (185 nm)

The resin article 610 was placed on a sample table in a chamber having the above illuminance distribution. The resin article 610 was irradiated with the ultraviolet light for 4 min and 15 sec while being rotated using a sample table rotation function possessed by UV-300. Note that, in Examples 1, 2, and 3, the irradiation was performed under conditions that the irradiate distance was 3.5 cm, and the resin article 610 was fixed to the highest illuminance point.

The surface of the portion 810 after the conditioner treatment in which the plating layer 620 was to be formed was measured using an atomic force microscopy (AFM) (scanning probe microscope JSPM-4210, manufactured by JEOL Ltd.), to find that the surface roughness Ra was 1.25 nm.

When the resin article with plating layer 600 thus obtained was viewed from a side on which the plating layer 620 was not formed, the plating layer 620 did not exhibit a black color, and gloss peculiar to metal was visually recognized. For the resin article with plating layer 600 thus obtained, the reflectance of the plating layer 620 through the resin article 610 was measured from a side on which the plating layer 620 was not formed, using a microspectroscopic system (DF-1037, manufactured by Techno-Synergy, Inc.). The measurement result is shown in FIG. 9.

As shown in FIG. 9, in Comparative Example 1 in which the modified portion had a low surface roughness, the plating layer 620 did not sufficiently exhibit a black color at an interface portion between the resin article 610 and the plating layer 620 as viewed from a side on which the plating layer 620 was not formed. On the other hand, in Examples 1-4 in which the modified portion had a high surface roughness, the plating layer 620 (the conductor 520) exhibited a black color as viewed in a similar manner. In particular, in Examples 2, 3, and 4 in which a combination of ultraviolet laser irradiation and ultraviolet lamp irradiation was performed, even when the irradiation time of the ultraviolet lamp was short, the modified portion had a sufficient surface roughness, and it was observed that the plating layer 620 (the conductor 520) exhibited a black color at an interface portion between the resin article 610 and the plating layer 620 (the conductor 520). By comparing Examples 2 and 3, it is found that as the number of times of ultraviolet laser irradiation increases, the reflectance of the plating layer 620 at the interface portion between the resin article 610 and the plating layer 620 decreases. It is also found that not only when the surface roughness is excessively low, but also when the surface roughness is excessively high, the reflectance of the plating layer 620 at the interface portion between the resin article 610 and the plating layer 620 tends to increase.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Applications No. 2014-078220, filed Apr. 4, 2014, No. 2014-160782, filed Aug. 6, 2014, and No. 2014-265249, filed Dec. 26, 2014, which are hereby incorporated by reference herein in their entirety.

What is claimed is:

1. A conductive film comprising:
a resin article having a modified portion on a surface thereof, the modified portion being formed by irradiation with an ultraviolet laser and an oxidation process after the irradiation with the ultraviolet laser;
a conductor provided by plating on the modified portion irradiated with the ultraviolet laser.

2. The conductive film according to claim 1, wherein
all or a portion of the conductor is buried in a recessed portion formed on the resin article.

3. A method for manufacturing a conductive film, comprising steps of:
irradiating a portion on which a conductor is to be formed on a resin article with an ultraviolet laser;
after the irradiating step, oxidizing the resin article;
after the oxidizing step, forming the conductor on the ultraviolet laser irradiated portion of the resin article, including performing electroless plating on the resin article.

4. The method according to claim 3, wherein
the forming step comprises:
after performing the electroless plating, performing electroplating on the resin article.

5. A resin article with plating layer comprising:
a resin article; and
a plating layer provided on a surface of the resin article,
wherein
the plating layer exhibits a black color.

6. The resin article with plating layer according to claim 5, wherein
the resin article has a modified portion on a surface, the modified portion being formed by irradiation with an ultraviolet laser and oxidation after the irradiation with the ultraviolet laser, and
the plating layer is provided by plating on the modified portion irradiated by the ultraviolet laser.

7. The resin article with plating layer according to claim 5, wherein
the resin article has a surface on which the plating layer is provided, the surface being formed from a material having optical transparency, and
the plating layer exhibits a black color at an interface between the plating layer and the resin article.

8. The resin article with plating layer according to claim 7, wherein
the resin article has a surface roughness Ra of 1.50 nm or more at the interface between the resin article and the plating layer.

9. The resin article with plating layer according to claim 7, wherein
a reflectance at the interface between the resin article and the plating layer is 0.3 or less with respect to light having a wavelength of 550 nm.

10. The resin article with plating layer according to claim 5, wherein
the plating layer exhibits the black color at an upper surface.

11. The resin article with plating layer according to claim 10, wherein
the upper surface of the plating layer from the resin article is formed from black plating.

12. The resin article with plating layer according to claim 5, wherein
the resin article includes polyolefin resin, polyester resin, or vinyl resin.

13. The resin article with plating layer according to claim 5, wherein
the resin article with plating layer is a conductive film, the resin article is a resin film included in the conductive film, and the plating layer is a conductor included in the conductive film.

14. A method for manufacturing a resin article with plating layer, comprising steps of:
modifying a portion of a surface of the resin article by irradiation with an ultraviolet light; and
forming the plating layer by plating on the portion of the surface of the resin article, the plating layer exhibiting a black color.

15. The method according to claim 14, wherein
the modifying step comprises
altering the portion of the surface of the resin article into a rough surface by the ultraviolet light irradiation.

16. The method according to claim 14, wherein
the modifying step comprises
irradiating the portion of the surface of the resin article with an ultraviolet laser of 243 nm or less, and
after the irradiating step, oxidizing a region including the portion of the surface of the resin article, to modify the surface of the resin article.

17. The method according to claim 16, wherein
the oxidizing step comprises
performing irradiation with ultraviolet light having a wavelength of 243 nm or less.

18. The method according to claim 16, wherein
the irradiating step and the oxidizing step are performed in an atmosphere containing at least one of oxygen and ozone.
